(19) United States
(12) Patent Application Publication
(10) Pub. No.: US 2025/0070494 A1
(43) Pub. Date: Feb. 27, 2025

(54) Flexible Interconnect Circuits Comprising Spring Contacts

(71) Applicant: CelLink Corporation, San Carlos, CA (US)

(72) Inventors: Lewis Richard Galligan, Novi, MI (US); Andrew Fisher, Novi, MI (US)

(73) Assignee: CelLink Corporation, San Carlos, CA (US)

(21) Appl. No.: 18/814,137

(22) Filed: Aug. 23, 2024

Related U.S. Application Data
(60) Provisional application No. 63/578,920, filed on Aug. 25, 2023.

(51) Int. Cl. H01R 12/77

(52) U.S. Cl. CPC H01R 12/777

(57) ABSTRACT

Described herein are flexible interconnect circuits comprising spring contacts, methods of fabricating such circuits, as well as methods of using such circuits to form electrical connections to various components. A flexible interconnect circuit comprises two insulators and one or more conductive traces, at least partially protruding between the insulators. The circuit also comprises one or more spring contacts, each comprising a base portion and a spring portion, which is monolithic with the base portion. The base portion directly interfaces, is mechanically attached, and is electrically connected to one of the protruding portions of the conductive traces forming a trace-contact interface. The spring portion is configured to flex relative to the base portion at least in a direction substantially perpendicular to the trace-contact interface. In some examples, multiple spring contacts are attached to the same protruding portion and are offset along the width of this portion.

### CROSS-REFERENCE TO RELATED APPLICATIONS

This application claims the benefit under 35 U.S.C. § 119 (e) of U.S. Provisional Patent Application 63/578,920 (Attorney Docket No. CLNKP024P) by Lewis Richard Galligan, entitled: “Flexible Interconnect Circuits Comprising Spring Contacts”, filed on 2023 Aug. 25, which is incorporated herein by reference in its entirety for all purposes.

### BACKGROUND

Electrical power and control signals are typically transmitted to individual components of a vehicle or any other machinery or system using multiple wires bundled together in a harness. In a conventional harness, each wire may have a round cross-sectional profile and may be individually surrounded by an insulating sleeve. The cross-sectional size of each wire is selected based on the material and the current transmitted by this wire. Furthermore, resistive heating and thermal dissipation are a concern during electrical power transmission requiring even larger cross-sectional sizes of wires in a conventional harness. As a result, harnesses can be rather bulky, heavy, and expensive to manufacture. Yet, automotive, aerospace and other industries strive for smaller, lighter, and less expensive components. Flexible interconnect circuits can be fabricated with thin profiles using conductive traces formed by patterning metal foils/sheets. However, forming electrical connections to these circuits or, more specifically, to these flat conductive traces can be challenging because of their unique width-to-thickness ratios.

### SUMMARY

Described herein are flexible interconnect circuits comprising spring contacts, methods of fabricating such circuits, as well as methods of using such circuits to form electrical connections to various components. A flexible interconnect circuit comprises two insulators and one or more conductive traces, at least partially protruding between the insulators. The circuit also comprises one or more spring contacts, each comprising a base portion and a spring portion, which is monolithic with the base portion. The base portion directly interfaces, is mechanically attached, and is electrically connected to one of the protruding portions of the conductive traces forming a trace-contact interface. The spring portion is configured to flex relative to the base portion at least in a direction substantially perpendicular to the trace-contact interface. In some examples, multiple spring contacts are attached to the same protruding portion and are offset along the width of this portion.

In some aspects, the techniques described herein relate to a flexible interconnect circuit including: a first insulator; a second insulator; a conductive trace at least partially protruding between the first insulator and the second insulator and including a trace contact portion extending past at least one of the first insulator and the second insulator; and a spring contact including a base portion and a spring portion monolithic with the base portion, wherein: the base portion directly interfaces and is mechanically attached and electrically connected to the trace contact portion forming a trace-contact interface, and the spring portion is configured to flex relative to the base portion at least in a direction substantially perpendicular to the trace-contact interface.

In some aspects, the techniques described herein relate to a flexible interconnect circuit, wherein the spring portion includes a first sub-arch spring portion 142a and a second sub-arch spring portion 142b, including first ends and second ends such that the first ends are monolithic with the base portion and the second ends extend toward each other and are separated by a gap thereby enhancing flexibility of the first sub-arch spring portion 142a and the second sub-arch spring portion 142b.

In some aspects, the techniques described herein relate to a flexible interconnect circuit, wherein the trace contact portion is flexible.

In some aspects, the techniques described herein relate to a flexible interconnect circuit, wherein the trace contact portion further interfaces the second insulator such that the trace contact portion is positioned between the second insulator and the base portion.

In some aspects, the techniques described herein relate to a flexible interconnect circuit, further including a stiffening unit such that the trace contact portion is positioned between the stiffening unit and the base portion, wherein: the stiffening unit includes a material selected from the group consisting of (1) a composite including a fiberglass cloth and an epoxy resin, and (2) polycarbonate, and the stiffening unit has a thickness of between 2 millimeters and 6 millimeters.

In some aspects, the techniques described herein relate to a flexible interconnect circuit, wherein: the trace contact portion further interfaces the second insulator, the second insulator is at least partially positioned between the trace contact portion and the stiffening unit, and the stiffening unit is mechanically attached to the second insulator.

In some aspects, the techniques described herein relate to a flexible interconnect circuit, wherein the spring contact includes a steel core and a surface layer formed from one or more of copper, tin, and silver.

In some aspects, the techniques described herein relate to a flexible interconnect circuit, wherein the spring contact is narrower than the trace contact portion and is not attached to any other conductive traces of the flexible interconnect circuit.

In some aspects, the techniques described herein relate to a flexible interconnect circuit, wherein each of the conductive trace and the spring contact has a current rating of 2-20 Amps.

In some aspects, the techniques described herein relate to a flexible interconnect circuit, wherein each of the conductive trace and the spring contact has a current rating of 20-40 Amps.

In some aspects, the techniques described herein relate to a flexible interconnect circuit, wherein the trace contact portion is attached to the spring contact and at least one additional spring contact.

In some aspects, the techniques described herein relate to a flexible interconnect circuit, further includes an additional conductive trace at least partially protruding between the first insulator and the second insulator, wherein: the additional conductive trace includes an additional trace contact portion extending past at least one of the first insulator and the second insulator, and the base portion of the spring contact further directly interfaces and is mechanically attached and electrically connected to the additional trace contact portion forming an additional trace-contact interface.

In some aspects, the techniques described herein relate to a flexible interconnect circuit, wherein the spring contact has a current rating of 200-600 Amps.

In some aspects, the techniques described herein relate to a flexible interconnect circuit, wherein the spring contact has a voltage rating of at least 400 Volts.

In some aspects, the techniques described herein relate to a flexible interconnect circuit, wherein: the base portion includes a first sub-base and a second sub-base, extending parallel to the first sub-base and positioned further away from the first insulator, the spring portion includes a plurality of arch portions, extending parallel to each other and arching over the base portion and each including a first end and a second end, the first end of each of the plurality of arch portions is connected to the first sub-base, and the second end of each of the plurality of arch portions is connected to the second sub-base.

In some aspects, the techniques described herein relate to a flexible interconnect circuit, wherein the first sub-base, the second sub-base, and the plurality of arch portions are monolithic.

In some aspects, the techniques described herein relate to a flexible interconnect circuit, wherein the base portion further includes a bridging portion, extending between and monolithic with the first sub-base and the second sub-base.

In some aspects, the techniques described herein relate to a flexible interconnect circuit, further includes an additional conductive trace and an additional spring contact, wherein: the second insulator is positioned between the conductive trace and the additional conductive trace forming a stack and electronically isolating the conductive trace from the additional conductive trace, and the additional spring contact directly interfaces and is mechanically attached and electrically connected to the additional conductive trace such that a stack of the conductive trace, the second insulator, and the additional conductive trace is positioned between the spring contact and the additional spring contact.

In some aspects, the techniques described herein relate to a flexible interconnect circuit, wherein the second insulator extends past the first insulator and also past each of the spring contact and the additional spring contact thereby preventing arcing between the spring contact and the additional spring contact.

In some aspects, the techniques described herein relate to a flexible interconnect circuit, further including a third insulator, wherein: the additional conductive trace at least partially protrudes between the third insulator and the second insulator and includes an additional trace contact portion extending past at least one of the third insulator and the second insulator, the additional spring contact includes an additional base portion and an additional spring portion monolithic with the additional base portion, the additional base portion directly interfaces and is mechanically attached and electrically connected to the additional trace contact portion forming an additional trace-contact interface, parallel to the trace-contact interface, and the additional spring portion is configured to flex relative to the additional base portion at least in a direction substantially perpendicular to the additional trace-contact interface.

In some aspects, the techniques described herein relate to a flexible interconnect circuit, further including a shield and a shield insulator, wherein: the conductive trace is stacked between the shield and the additional conductive trace, and the shield is stacked between the shield insulator and the first insulator.

In some aspects, the techniques described herein relate to a flexible interconnect circuit, further including an additional shield and an additional shield insulator, wherein: the additional conductive trace is stacked between the additional shield and the conductive trace, both the conductive trace and the additional conductive trace are stacked between the shield and the additional shield, and the additional shield is stacked between the additional shield insulator and the third insulator.

In some aspects, the techniques described herein relate to a flexible interconnect circuit, further including a third insulator, a fourth insulator, an additional conductive trace at least partially protruding between the third insulator and the fourth insulator and including an additional contact portion extending past at least one of the third insulator and the fourth insulator, and an additional spring contact including an additional base portion and an additional spring portion monolithic with the additional base portion, wherein: the additional base portion directly interfaces and is mechanically attached and electrically connected to the additional contact portion forming an additional trace-contact interface, and the additional spring portion is configured to flex relative to the additional base portion at least in a direction substantially perpendicular to the additional trace-contact interface.

In some aspects, the techniques described herein relate to a flexible interconnect circuit, further including a carrier including a first protrusion and a second protrusion, wherein: the spring contact includes an edge including a spring-contact alignment notch, the spring contact is aligned with the carrier such that the first protrusion of the carrier aligns with the spring-contact alignment notch, the additional spring contact includes an edge including an additional spring-contact alignment notch, and the additional spring contact is aligned with the carrier such that the second protrusion of the carrier aligns with the additional spring-contact alignment notch.

In some aspects, the techniques described herein relate to a flexible interconnect circuit, further including a shield enclosure including a first contact opening and a second contact opening, wherein the carrier, the spring contact, and the additional spring contact are positioned within the shield enclosure such that at least a portion of the spring contact protrudes the first contact opening and at least a portion of the additional spring contact protrudes through the second contact opening.

In some aspects, the techniques described herein relate to a flexible interconnect circuit, wherein the trace-contact interface is sufficiently planar.

In some aspects, the techniques described herein relate to a flexible interconnect circuit, wherein the spring portion forms an arched loop over the base portion.

In some aspects, the techniques described herein relate to a flexible interconnect circuit, wherein the base portion is mechanically attached and electrically connected to the trace contact portion using laser welding, ultrasonic welding, and soldering.

In some aspects, the techniques described herein relate to a flexible interconnect circuit, wherein the conductive trace has a thickness of at least 100 micrometers.

In some aspects, the techniques described herein relate to a flexible interconnect circuit, wherein the conductive trace includes aluminum.

In some aspects, the techniques described herein relate to a flexible interconnect circuit, wherein: the spring contact includes at least one spring-contact alignment notch, the conductive trace includes at least one conductive-trace alignment notch, and the at least one spring-contact alignment notch is aligned with the at least one conductive-trace alignment notch.

In some aspects, the techniques described herein relate to a flexible interconnect circuit, wherein the spring contact includes an edge extending past the first insulator and the second insulator in at least one direction a distance of DN.

In some aspects, the techniques described herein relate to a flexible interconnect circuit, wherein the base portion includes a surface opposite the conductive trace and at least one overpressure-limiting boss protruding from the surface.

In some aspects, the techniques described herein relate to a flexible interconnect circuit, wherein: the at least one overpressure-limiting boss protrudes from the surface a distance of TB measured in a direction substantially perpendicular to the trace-contact interface, the spring portion protrudes from the surface a distance of TS measured in a direction substantially perpendicular to the trace-contact interface, and the distance TS is greater than the distance TB.

In some aspects, the techniques described herein relate to an assembly including: a flexible interconnect circuit including a first insulator, a second insulator, a conductive trace at least partially protruding between the first insulator and the second insulator and including a trace contact portion extending past at least one of the first insulator and the second insulator and a spring contact including a base portion and a spring portion monolithic with the base portion including a base portion and a spring portion monolithic with the base portion, electrically and mechanically coupled with the conductive trace forming a trace-contact interface, wherein the spring portion is configured to flex relative to the base portion at least in a direction substantially perpendicular to the trace-contact interface; an additional flexible interconnect circuit including an additional first insulator, an additional second insulator, an additional conductive trace at least partially protruding between the additional first insulator and the additional second insulator and including an additional trace contact portion extending past at least one of the additional first insulator and the additional second insulator and an additional spring contact including an additional base portion and an additional spring portion monolithic with the additional base portion, electrically and mechanically coupled with the additional conductive trace forming an additional trace-contact interface, wherein the additional spring portion is configured to flex relative to the additional base portion at least in a direction substantially perpendicular to the additional trace-contact interface; a stiffener positioned between the flexible interconnect circuit and the additional flexible interconnect circuit; and a connector body directly interfacing the flexible interconnect circuit and the additional flexible interconnect circuit and configured to urge the flexible interconnect circuit and the additional flexible interconnect circuit towards the stiffener.

In some aspects, the techniques described herein relate to an assembly, further including a blade header including: a blade-header axis; a blade conductor extending parallel with the blade-header axis; an additional blade conductor extending parallel with and electrically isolated from the blade conductor; and a pressure ramp positioned at an end of the blade header and between the blade conductor and the additional blade conductor, wherein: the pressure ramp is configured to apply forces to the flexible interconnect circuit and the additional flexible interconnect circuit when the flexible interconnect circuit and the additional flexible interconnect circuit are inserted into the blade header, urging the spring portion towards the blade conductor and the additional spring portion towards the additional blade conductor, thereby electrically connecting the conductive trace with the blade conductor and the additional conductive trace with the additional blade conductor.

In some aspects, the techniques described herein relate to an assembly, wherein the blade header further includes a conductor support interfacing the blade conductor, configured to mechanically support the blade conductor against a force applied by the spring portion when the pressure ramp applies a force to urge the spring portion towards the blade conductor.

In some aspects, the techniques described herein relate to an assembly, further including: a third flexible interconnect circuit including a third conductive trace and a third spring contact electrically and mechanically coupled with the third conductive trace, including a third base portion and a third spring portion monolithic with the third base portion; a fourth flexible interconnect circuit including a fourth conductive trace and a fourth spring contact electrically and mechanically coupled with the fourth conductive trace, including a fourth base portion and a fourth spring portion monolithic with the fourth base portion; an additional stiffener positioned between the third flexible interconnect circuit and the fourth flexible interconnect circuit; and an additional connector body directly interfacing the third flexible interconnect circuit and the fourth flexible interconnect circuit and configured to urge the third flexible interconnect circuit and the fourth flexible interconnect circuit towards the additional stiffener, wherein: the blade header further includes an additional pressure ramp positioned at an opposite end of the blade header from the pressure ramp, and the additional pressure ramp is configured to apply forces to the third flexible interconnect circuit and the fourth flexible interconnect circuit when the third flexible interconnect circuit and the fourth flexible interconnect circuit are inserted into the blade header, urging the third spring portion towards the blade conductor and the fourth spring portion towards the additional blade conductor, thereby electrically connecting the third conductive trace with the blade conductor and the fourth conductive trace with the additional blade conductor.

In some aspects, the techniques described herein relate to an assembly, wherein the blade header protrudes through an opening in a mounting surface and the blade conductor and the additional blade conductor are electrically isolated from the mounting surface.

In some aspects, the techniques described herein relate to a method of fabricating a flexible interconnect circuit, the method including: providing a flexible interconnect circuit subassembly including a first insulator and a conductive trace laminated to the first insulator and including a trace contact portion extending past at least one of the first insulator; providing a spring contact including a base portion and a spring portion monolithic with the base portion; and attaching the base portion of the spring contact to the trace contact portion of the flexible interconnect circuit subassembly such that, after attaching: the base portion directly interfaces and is mechanically attached and electrically connected to the trace contact portion forming a trace-contact interface, and the spring portion is configured to flex relative to the base portion at least in a direction substantially perpendicular to the trace-contact interface.

In some aspects, the techniques described herein relate to a method, wherein attaching the base portion of the spring contact to the trace contact portion of the flexible interconnect circuit subassembly includes one or more laser welding, ultrasonic welding, and soldering.

In some aspects, the techniques described herein relate to a method, wherein, while attaching the base portion of the spring contact to the trace contact portion of the flexible interconnect circuit subassembly, a portion of a surface of the trace contact portion, facing away from the base portion, is exposed.

In some aspects, the techniques described herein relate to a method, further including, after attaching the base portion of the spring contact to the trace contact portion of the flexible interconnect circuit subassembly, laminating a second insulator to the conductive trace such that the portion of the surface of the trace contact portion, facing away from the base portion, is covered with the second insulator.

In some aspects, the techniques described herein relate to a method, wherein providing the flexible interconnect circuit subassembly includes patterning a metal foil to form a conductive trace such that the conductive trace is laminated to and supported by the first insulator relative to other conductive traces formed from one metal foil.

In some aspects, the techniques described herein relate to a method of connecting a flexible interconnect circuit to an external device, the method including: providing the flexible interconnect circuit including a first insulator, a second insulator, a conductive trace, and a spring contact, wherein: the conductive trace at least partially protrudes between the first insulator and the second insulator and includes a trace contact portion extending past at least one of the first insulator and the second insulator, the spring contact includes a base portion and a spring portion monolithic with the base portion, the base portion directly interfaces and is mechanically attached and electrically connected to the trace contact portion forming a trace-contact interface, and the spring portion is configured to flex relative to the base portion at least in a direction substantially perpendicular to the trace-contact interface; providing the external device including an external-device conductive trace; and pressing the spring portion of the spring contact against the external-device conductive trace of the external device such that, during pressing, the spring portion deforms and is positioned closer to the base portion.

In some aspects, the techniques described herein relate to a method, wherein the external device is selected from the group consisting of a car component.

In some aspects, the techniques described herein relate to a method, wherein: the external device includes a set of retaining protrusions, the second insulator includes a set of openings, and pressing the spring portion of the spring contact against the external-device conductive trace of the external device further includes extending the set of retaining protrusions through the set of openings.

In some aspects, the techniques described herein relate to a method, wherein, after pressing the spring portion of the spring contact against the external-device conductive trace of the external device, the flexible interconnect circuit is mechanically coupled to the external device.

In some aspects, the techniques described herein relate to a method, wherein pressing the spring portion of the spring contact against the external-device conductive trace of the external device coincides with pressing an additional spring portion of an additional spring contact against an external-device conductive trace of the external device.

In some aspects, the techniques described herein relate to a flexible interconnect circuit including: a first insulator; a second insulator; a conductive trace at least partially protruding between the first insulator and the second insulator and including a trace contact portion extending past at least one of the first insulator and the second insulator; and a connection tab, including at least two of connection openings and directly interfacing and is mechanically attached and electrically connected to the trace contact portion forming a trace-contact interface.

In some aspects, the techniques described herein relate to a flexible interconnect circuit, wherein the connection openings are aligned along an axis perpendicular to the length of the conductive trace.

In some aspects, the techniques described herein relate to a flexible interconnect circuit, further including a reinforcement component, attached to connection tab and overlapping with all of the connection openings such that the connection openings further protrude through the reinforcement component.

In some aspects, the techniques described herein relate to a flexible interconnect circuit, further including an additional reinforcement component, attached to connection tab such that the connection tab is positioned between the reinforcement component and the additional reinforcement component, wherein the additional reinforcement component overlaps with all of the connection openings such that the connection openings further protrude through the additional reinforcement component.

In some aspects, the techniques described herein relate to a flexible interconnect circuit, wherein the reinforcement component is offset relative to the conductive trace such that neither one of the connection openings protrudes through the conductive trace.

In some aspects, the techniques described herein relate to an assembly including: a first flexible interconnect circuit including a first conductive trace, a first connector body, and a first set of connector units, each connected to the first conductive trace and supported by the first connector body; a second flexible interconnect circuit including a second conductive trace, a second connector body, and a second set of connector units, at least one connected to the second conductive trace and supported by the second connector body; and a modular junction connector, including a connector body and a set of interconnecting units supported by the connector body, wherein: the connector body includes a first open cavity and a second open cavity, separated by a wall such that an opening of the first open cavity faces in an opposite direction from an opening of the second open cavity, the set of interconnecting units protrude through the wall and partially extend into each of the first open cavity and the second open cavity, one of the set of interconnecting units protrude into one in the first set of connector units and also into one of the second set of connector units thereby interconnecting the first conductive trace and the second conductive trace, the first connector body at least partially extends into the first open cavity and is interlocked with the connector body, and the second connector body at least partially extends into the second open cavity and is interlocked with the connector body.

In some aspects, the techniques described herein relate to an assembly, wherein the first set of connector units and the second set of connector units have a different number of units.

In some aspects, the techniques described herein relate to an assembly, wherein a third connector body at least partially extends into the first open cavity and is interlocked with the connector body.

In some aspects, the techniques described herein relate to an assembly, wherein the third connector body is a part a third flexible interconnect circuit, separate from the first flexible interconnect circuit.

In some aspects, the techniques described herein relate to an assembly, wherein the first connector body includes an interlocking unit, interlocked with the connector body.

These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, and methods. These drawings in no way limit any changes in form and detail that may be made by one skilled in the art without departing from the spirit and scope of the disclosed implementations.

FIGS. 1A and 1B are side and top schematic views of a flexible interconnect circuit comprising multiple conductive traces such that each trace is attached to a separate spring contact, in accordance with some examples.

FIG. 1C is a top schematic view of another example of the flexible interconnect circuit comprising multiple spring contacts attached to the same conductive trace.

FIGS. 1D and 1E are side and top schematic views of a spring contact, in accordance with some examples.

FIGS. 1F and 1G are top and side schematic views of a flexible interconnect circuit comprising a spring contact comprising a first sub-arch spring portion and a second sub-arch spring portion, in accordance with some examples.

FIG. 1H is a bottom schematic view of a carrier component of a flexible interconnect circuit, in accordance with some examples.

FIGS. 1I and 1J are a top schematic view and an exploded schematic side view of a flexible interconnect circuit comprising a shield enclosure, a spring contact, and a additional spring contact 185, in accordance with some examples.

FIGS. 2A and 2B are side and top schematic views of a flexible interconnect circuit comprising multiple narrow conductive traces, all connected to the same spring contact comprising multiple spring portions that are monolithic with one base portion, in accordance with some examples.

FIG. 2C is a top schematic view of a flexible interconnect circuit comprising a wide conductive trace connected to a spring contact comprising multiple spring portions that are monolithic with one base portion, in accordance with some examples.

FIGS. 3A and 3B are side schematic views of two examples of a flexible interconnect circuit comprising two spring contacts, attached to the opposite sides of the circuit, in accordance with some examples.

FIGS. 3C and 3D are schematic top and side views of an example of a flexible interconnect circuit comprising a first insulator, a second insulator, a conductive trace, and a spring contact, in accordance with some examples.

FIG. 3E is a schematic side view of an example of an assembly comprising the flexible interconnect circuit of FIG. 3C, an additional flexible interconnect circuit, a stiffener, and a connector body, in accordance with some examples.

FIG. 3F is a schematic side view of an assembly interconnecting two pairs of flexible interconnect circuits, in accordance with some examples.

FIG. 4 is a process flowchart corresponding to a method of fabricating a flexible interconnect circuit comprising one or more spring contacts connected to one or more conductive traces, in accordance with some examples.

FIG. 5 is a process flowchart corresponding to a method of forming electrical connections to a flexible interconnect circuit using one or more spring contacts of the circuit, in accordance with some examples.

FIGS. 6A-6F are schematic views of different stages of the method in FIG. 5, in accordance with some examples.

FIG. 6G is a schematic view of the flexible interconnect circuit used for connecting various components of the car door, in accordance with some examples.

FIGS. 7A and 7B are top schematic views of two examples of a flexible interconnect circuit comprising a connection tab with two connection openings.

FIGS. 7C and 7D are side schematic views of two examples of a flexible interconnect circuit comprising a connection tab and one or more reinforcement components.

FIGS. 7E and 7F are top and side schematic views of a reinforcement component attached directly to a conductive trace, in accordance with some examples.

FIGS. 8A and 8B are schematic cross-sectional views of an assembly comprising three flexible interconnect circuits and a modular junction connector before and after interconnecting these flexible interconnect circuits using the modular junction connector, in accordance with some examples.

FIGS. 8C and 8D are two cross-sectional views of the modular junction connector in FIG. 8B with connector body extending into the connector's cavity and the set of interconnecting units extending in and connecting to the sockets, in accordance with some examples.

FIGS. 8E and 8F are schematic cross-sectional views of two additional examples of an assembly comprising three flexible interconnect circuits and a modular junction connector before interconnecting these flexible interconnect circuits using the modular junction connector.

FIG. 9A is a cross-sectional view of a modular junction connector and multiple connector body extending into the two connector's cavities.

FIG. 9B is a front view of the modular junction connector in FIG. 9A.

FIG. 9C is a front view of another example of the modular junction illustrating one cavity.

FIGS. 9D and 9E are front and side cross-sectional views of the connector portion of the flexible interconnect circuit used in FIG. 9A, in accordance with some examples.

FIGS. 9F-9H illustrate additional examples of the connector portion of the flexible interconnect circuit, in accordance with some examples.

FIG. 10A is a schematic cross-sectional view of a connector portion of the flexible interconnect circuit, in accordance with some examples.

FIGS. 10B-10E are schematic cross-sectional views illustrating different stages during the fabrication of the connector portion of the flexible interconnect circuit in FIG. 10A, in accordance with some examples.

FIG. 10F is a schematic cross-sectional view of a connector portion of the flexible interconnect circuit, in accordance with some examples.

FIGS. 11A-11C are additional examples of the connector portion of the flexible interconnect circuit, in accordance with some examples.

### DETAILED DESCRIPTION

In the following description, numerous specific details are outlined to provide a thorough understanding of the presented concepts. In some examples, the presented concepts are practiced without some or all of these specific details. In other examples, well-known process operations have not been described in detail to unnecessarily obscure the described concepts. While some concepts will be described in conjunction with specific examples, it will be understood that these examples are not intended to be limiting.

Flexible interconnect circuits are used to deliver power and/or signals and are used for various applications, such as vehicles, appliances, electronics, and the like. One example of such flexible interconnect circuits is a harness. As noted above, a conventional harness uses a stranded set of small round wires. A separate polymer shell insulates each wire, adding to the size and weight of the harness. Unlike conventional harnesses, flexible interconnect circuits described herein have thin flat profiles, enabled by thin electrical conductors that can be positioned side-by-side. Each electrical conductor can have a flat rectangular profile. In some examples, electrical conductors (positioned next to each other) are formed from the same metal sheet (e.g., foil). For purposes of this disclosure, the term “interconnect” is used interchangeably with “interconnect circuit”, the term “conductive layer”—with “conductor” or “conductor layer”, and the term “insulating layer”—with “insulator”.

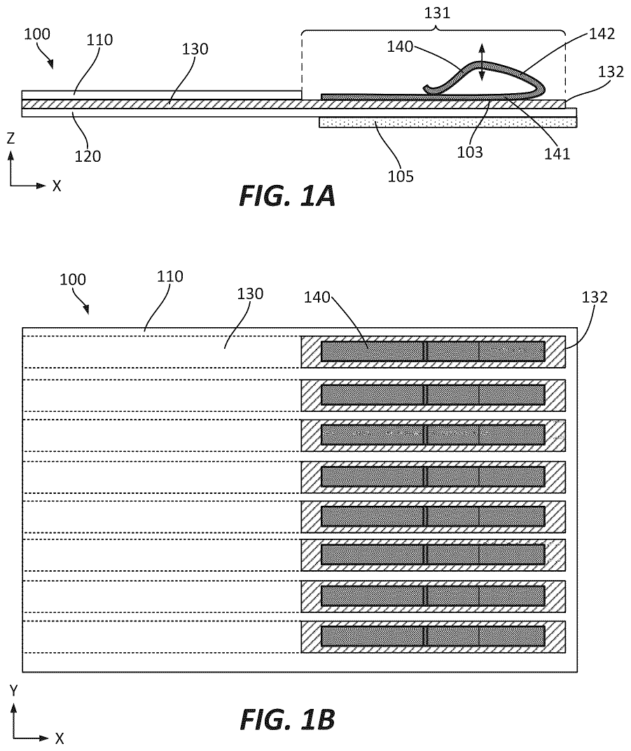

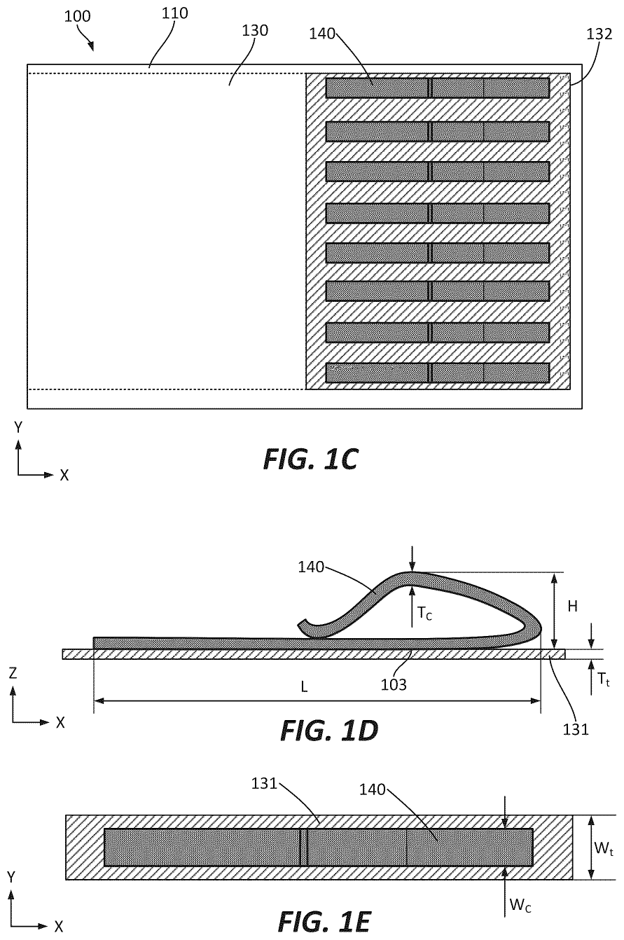

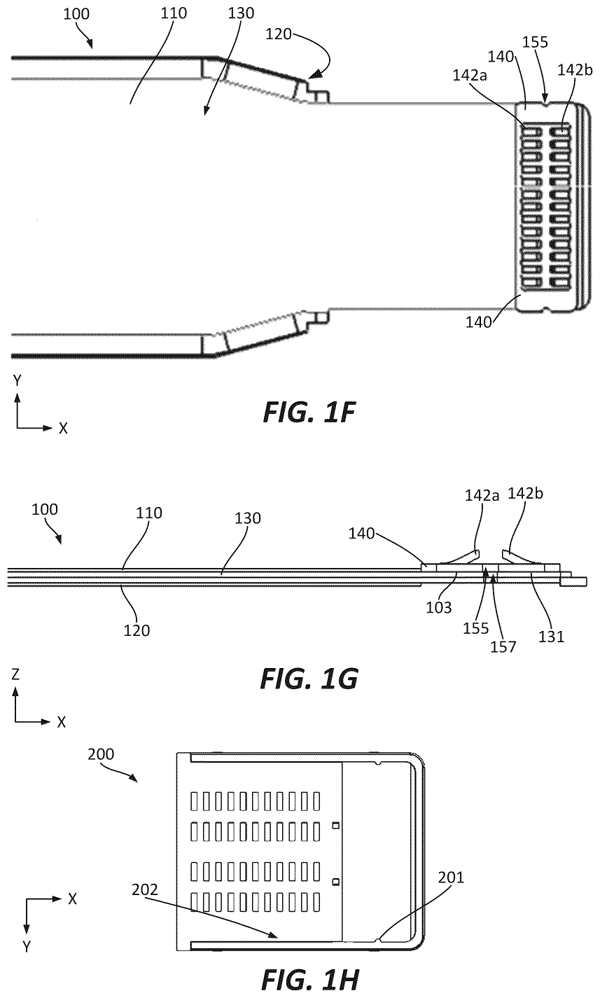

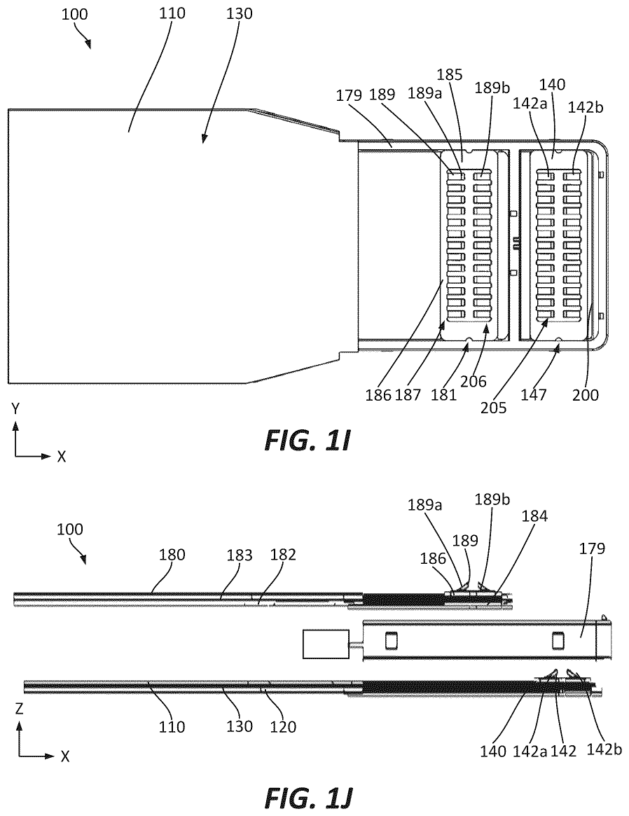

FIGS. 1A-1E—Examples of Flexible Interconnect Circuits with Spring Contacts

FIGS. 1A and 1B illustrate side and top schematic views of flexible interconnect circuit 100 comprising multiple conductive traces 130 such that each conductive trace 130 is attached to separate spring contact 140, which may be also referred to as lamellas. Flexible interconnect circuit 100 also comprises first insulator 110 and second insulator 120. As shown in FIGS. 1A and 1B, conductive trace 130 at least partially protrudes between first insulator 110 and second insulator 120 and further comprises trace contact portion 131 extending past at least one of first insulator 110 and second insulator 120 and terminating at trace end 132. Trace end 132 stops short of the full length of second insulator 120 and optionally stiffening unit 105. Therefore, a protrusion is created by second insulator 120, e.g., to protect trace end 132 from mechanical damage and/or electric shorts.

In some examples, conductive trace 130 has a thickness of at least 100 micrometers, at least 300 micrometers, or at least 500 micrometers. With such a large thickness of conductive traces 130, flexible interconnect circuit 100 can be used for various high-current applications (e.g., battery bus bars). It should be noted that forming a pattern of conductive traces 130 with such large thicknesses is not possible with some technologies, e.g., chemical etching. In some examples, conductive trace 130 comprises aluminum, copper, and the like. It should be noted that using aluminum in flexible interconnect circuit 100 can be challenging from the patterning and connecting perspectives.

Spring contact 140 comprises base portion 141 and spring portion 142, which is monolithic with base portion 141. In some examples, spring portion 142 forms an arched loop over base portion 141. Base portion 141 directly interfaces and is mechanically attached and electrically connected (e.g., laser welds, ultrasonic welds) to trace contact portion 131 forming trace-contact interface 103. In some examples, trace-contact interface 103 is sufficiently planar. Spring portion 142 is configured to flex relative to base portion 141 at least in a direction substantially perpendicular to trace-contact interface 103 (the Z-direction in FIG. 1A). Furthermore, optional stiffening unit 105 may be used below second insulator 120 to add the strength of flexible interconnect circuit 100 as a whole. Specifically, conductive trace 130 and, in some examples, second insulator 120 extends between spring contact 140 and stiffening unit 105.

FIG. 1B shows an example of flexible interconnect circuit 100 wherein each conductive trace 130 has its own individual spring contact 140. This example may be used when small currents need to be transmitted through each spring contact 140, e.g., for signal transmission.

Spring contact 140 enables forming electrical contacts in various applications with various components, e.g., printed circuit board (PCB) pads or other devices and circuits. Flexible interconnect circuit 100 is flat and exposure of spring contact 140 allows a direct and maintained contact with such connected components.

In some examples, flexible interconnect circuit 100 or, more specifically, trace contact portion 131 (e.g., in a stack with second insulator 120) is flexible, which can be defined as capable of forming a bend radius of less than 1 meter or less than 0.3 meters or even less than 0.1 meters. In some examples, trace contact portion 131 further interfaces second insulator 120 such that trace contact portion 131 is positioned between second insulator 120 and base portion 141.

First insulator 110 and second insulator 120 provide electrical isolation and mechanical support to conductive traces 130. In some examples, first insulator 110 and second insulator 120 may initially be processed in a sheet or roll form and may subsequently be laminated to the conductive layer using, for example, adhesive material. First insulator 110 and second insulator 120 may include (or be formed from) polyimide (PI), polyethylene naphthalate (PEN), polyethylene terephthalate (PET), polymethyl methacrylate (PMMA), ethyl vinyl acetate (EVA), polyethylene (PE), polyvinyl fluoride (PVF), polyamide (PA), and/or polyvinyl butyral (PVB). Additional aspects (e.g., thicknesses) of first insulator 110 and second insulator 120 are described below.

The thickness of one or both first insulator 110 and second insulator 120 may be between 1 micrometer and 500 micrometers or, more specifically, between 10 micrometers and 125 micrometers. In some examples, each of first insulator 110 and second insulator 120 includes an adhesive sublayer facing conductive traces, e.g., for lamination to conductive traces and also to each other. These adhesive sublayers may be also used for directly laminating first insulator 110 and second insulator 120 (beyond the conductive layer boundaries), e.g., for edge sealing of flexible interconnect circuit 100. In some examples, the surface of first insulator 110 and/or second insulator 120 (e.g., the surface facing away from conductive traces) comprises an adhesive sublayer for bonding this insulating layer to an external structure (e.g., a supporting panel). First insulator 110 and second insulator 120 provide the electrical isolation and mechanical support to conductive traces. Additional aspects (e.g., materials) of first insulator 110 and second insulator 120 are described elsewhere in this document. Furthermore, additional aspects of conductive traces 130 or, more generally, conductive traces formed by these traces are described elsewhere in this document (e.g., uniform thickness, materials, surface sublayers).

As noted above, trace contact portion 131 is used for connecting to spring contact 140 and may be referred to as an exposed portion. In some examples, the exposed portion comprises a contact interface layer, e.g., formed with electroless nickel immersion gold (ENIG). Specifically, a contact interface layer can be formed over a base layer of conductive traces 130, with the base layer formed from copper, aluminum, and the like. The contact interface layer can be used to reduce oxidation and improve the solderability of the base layer. The contact interface layer can be formed by electroless nickel plating of the base layer followed by immersion in a solution comprising a gold-containing salt. During this immersion process, a portion of nickel is oxidized, while the gold ions are reduced to a metallic state and deposited on the surface. In some examples, palladium is used in addition to or instead of gold.

In some examples, conductive traces 130 have a uniform thickness throughout the entire circuit boundary. For example, conductive traces 130 can be formed from the same sheet of metal. More specifically, different (disjoint) portions of conductive traces 130 can be formed from the same sheet of metal. In some examples, all conductive traces 130 are formed from the same material, e.g., aluminum, copper, or the like. The use of aluminum (instead of copper) may help with lowering the overall circuit weight and also with lowering the minimum achievable fuse current rating. Specifically, aluminum has a higher resistivity and lower melting temperature than copper. As such, forming fusible links in an aluminum conductive layer may allow for more precise control of the fusible parameters (for the same size tolerance). In general, conductive traces 130 may be formed from any conductive material that is sufficiently conductive (e.g., a conductivity being greater than 10\hat{ }6 S/m or even greater than 10\hat{ }7 S/m to allow for current flow through the foil with low power loss.

In some examples, conductive traces 130 may include a surface sublayer or coating for providing a low electrical contact resistance and/or improving corrosion resistance. The surface sublayer may assist with forming electrical interconnections using techniques/materials including, but not limited to, soldering, laser welding, resistance welding, ultrasonic welding, bonding with conductive adhesive, or mechanical pressure. Surface sublayers that may provide a suitable surface for these connection methods include, but are not limited to, tin, lead, zinc, nickel, silver, palladium, platinum, gold, indium, tungsten, molybdenum, chrome, copper, alloys thereof, organic solderability preservative (OSP), or other electrically conductive materials. Furthermore, the surface sublayer may be sputtered, plated, cold-welded, or applied via other means. In some examples, the thickness of the surface sublayer may range from 0.05 micrometers to 10 micrometers or, more specifically, from 0.1 micrometers to 2.5 micrometers. Furthermore, in some examples, the addition of a coating of the OSP on top of the surface sublayer may help prevent the surface sublayer itself from oxidizing over time. The surface sublayer may be used when a base sublayer of conductive traces 130 includes aluminum or its alloys. Without protection, exposed surfaces of aluminum tend to form a native oxide, which is insulating. The oxide readily forms in the presence of oxygen or moisture. To provide a long-term stable surface in this case, the surface sublayer may be resistant to the in-diffusion of oxygen and/or moisture. For example, zinc, silver, tin, copper, nickel, chrome, or gold plating may be used as surface layers on an aluminum-containing base layer.

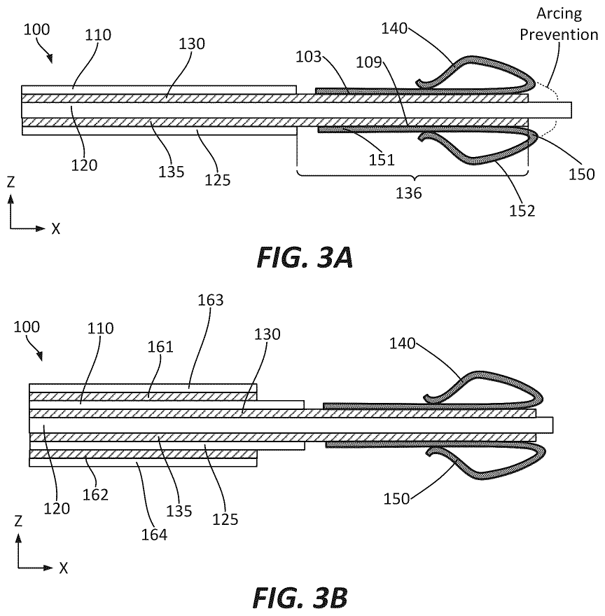

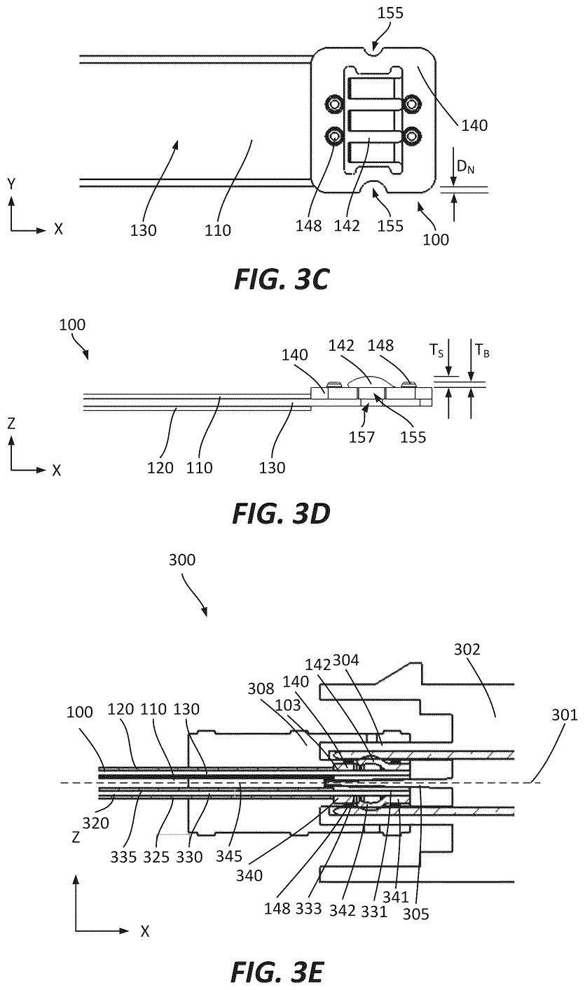

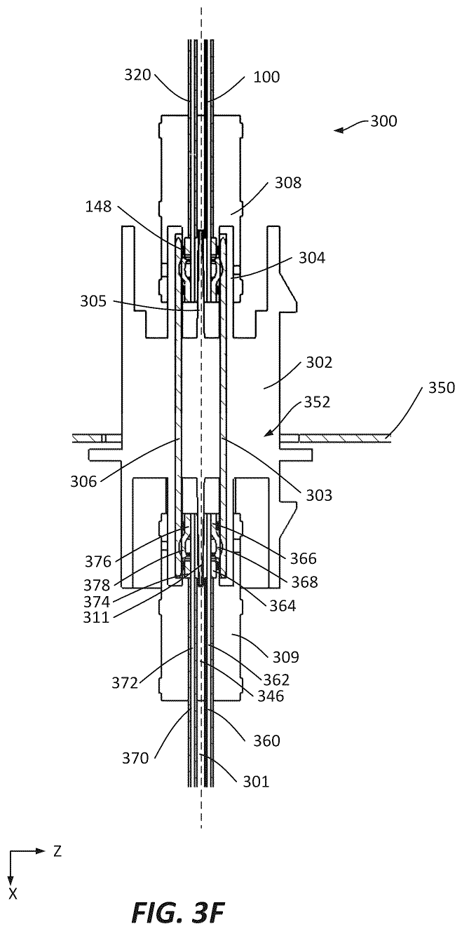

In some examples, conductive traces 130 can be arranged in either a single layer or multiple layers (e.g., as further described below with reference to FIGS. 3A and 3B). In some examples, conductive traces 130 in different layers are interconnected within flexible interconnect circuit 100. Furthermore, conductive traces 130 in the same layer can be interconnected or even monolithic with each other. It should be noted that conductive traces 130 in the same layer can be formed from the same sheet of metal.

In some examples, flexible interconnect circuit 100 further comprises stiffening unit 105 such that trace contact portion 131 is positioned between stiffening unit 105 and base portion 141. Stiffening unit 105 comprises a material selected from the group consisting of (1) a composite comprising a fiberglass cloth and an epoxy resin, (2) polycarbonate, and (3) metal. In some examples, stiffening unit 105 has a thickness of 2-6 millimeters or, more specifically, between 3-5 millimeters. Stiffening unit 105 can be adhered to (e.g., using a pressure-sensitive adhesive) or otherwise attached to second insulator 120. In some examples, stiffening unit 105 can be attached directly to conductive trace 130 (with no separate insulator layer present in between) and can be operable as an insulator for conductive trace 130.

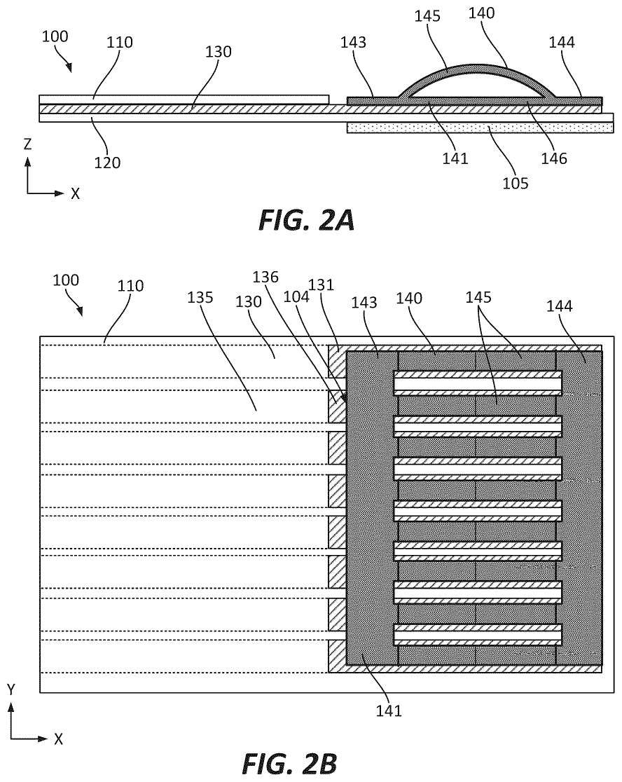

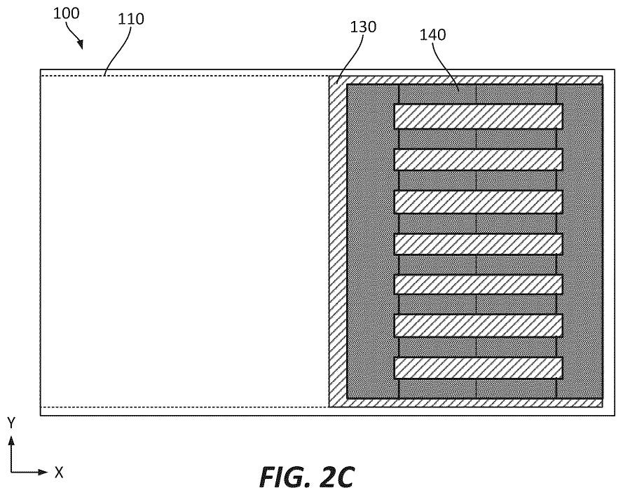

FIG. 1C illustrates a top schematic view of another example of flexible interconnect circuit 100 wherein, only one conductive trace 130 connects to multiple spring contacts 140, instead of FIG. 1B wherein each individual spring contact 140 has its own individual conductive trace 130. Because of the larger width of conductive trace 130 in FIG. 1C, this trace is capable of supporting larger currents (assuming the same thickness). Such large currents can be distributed across multiple spring contacts 140. Using multiple spring contacts 140 (vs. one large spring contact as in FIGS. 2B and 2C) provides various flexibilities in positioning these contacts on conductive trace 130.

FIGS. 1D and 1E illustrate side and top schematic views of spring contact 140 and trace contact portion 131. The dimensions of the spring contact 140 depend on the current rating of this contact, which in some examples can be 2-20 Amps or, more specifically, 5-15 Amps. In some examples, the current rating of ths contact is 20-40 Amps. Using multiple spring contacts 140 in parallel (e.g., as shown in FIG. 1C) allows for increasing the total current rating of this interconnection.

In some examples, spring contact 140 of flexible interconnect circuit 100 comprises a steel core and a surface layer formed from one or more of copper, tin, and silver. The steel core provides a spring action of the contact, e.g., allowing spring portion 142 to flex relative to base portion 141 while continuing to push up in this flex state (thereby maintaining the connection).

In some examples, spring contact 140 of flexible interconnect circuit 100 is narrower than trace contact portion 131 and is not attached to any other conductive traces of flexible interconnect circuit 100. For example, the width of spring contact 140 can be less than 90% than the width of trace contact portion 131 or, more specifically, less than 80% or even less than 70%.

In some examples, the spring portion 142 of the spring contact 140 comprises a first sub-arch spring portion 142a and a second sub-arch spring portion 142b. FIGS. 1F and 1G are top and side schematic views of a flexible interconnect circuit, in accordance with some examples. As illustrated in FIGS. 1F and 1G, in these examples, a first end of each of the first sub-arch spring portion 142a and second sub-arch spring portion 142b is monolithic with the base portion 141. However, the second ends of the first sub-arch spring portion 142a and second sub-arch spring portion 142b, which are opposite of the first ends, are separate by a gap and do not contact one another. The spring contact 140 may comprise two, more than two, more than four, more than eight, more than 20, or even more than 40 sub-arch spring portions. In some examples, the spring contact 140 comprises 26 sub-arch portions, arranged as 13 pairs of corresponding sub-arch portions. In some other examples, each first sub-arch spring portion 142a and second sub-arch spring portion 142b may be individually mechanically attached to and electrically coupled to either one conductive trace or individual conductive traces. A spring portion 142 comprising a first sub-arch spring portion 142a and a second sub-arch spring portion 142b may provide several benefits. Such examples may enhance flexibility of the spring portion 142 and thereby lower an insertion force required to connect the flexible interconnect circuit 100 with an external connector, compared with other examples of spring portions 142 described above. In addition, these examples may be less likely to collapse due to deformation caused by a high insertion force. By not collapsing, the pair of sub-arch springs better maintains application of force normal to the trace-contact interface 103.

In some examples, flexible interconnect circuit 100 comprises an additional conductive trace 183 and an additional spring contact 185. FIG. 1I is a top schematic view of a flexible interconnect circuit, in accordance with some examples. In these examples, the flexible interconnect circuit 100 further comprises a third insulator 180, a fourth insulator 182, an additional conductive trace 183, and an additional spring contact 185. The additional conductive trace 183 at least partially protrudes between the third insulator 180 and the fourth insulator 182. The additional conductive trace 183 comprises an additional contact portion 184 extending past at least one of the third insulator 180 and the fourth insulator 182. The additional spring contact 185 comprises an additional base portion 186 and an additional spring portion 189 monolithic with the additional base portion 186. In some further examples, as illustrated in FIG. 1I, the spring portion 142 comprises a first sub-arch spring portion 142a and a second sub-arch spring portion 142b and the additional spring portion 189 comprises an additional first sub-arch spring portion 189a and an additional second sub-arch spring portion 189b. The additional base portion 186 directly interfaces and is mechanically attached and electrically connected to the additional contact portion 184 forming an additional trace-contact interface 187. The additional spring portion 189 is configured to flex relative to the additional base portion 186 at least in a direction substantially perpendicular to the additional trace-contact interface 187. FIG. 1J is an exploded side view illustrating the relationships between the conductive trace 130, the additional conductive trace 183, the first insulator 110, the second insulator 120, the third insulator 180, the fourth insulator 182, the spring portion 142, and the additional spring portion 189.

FIG. 1H is a bottom schematic view of a carrier 200, in accordance with some examples. In some examples, the flexible interconnect circuit 100 further comprises the carrier 200. The carrier 200 comprises a first protrusion 201 and a second protrusion 202. The second protrusion 202 is not viewable in FIG. 1H. In these examples, the spring contact 140 comprises an edge comprising a spring-contact alignment notch 147. The spring contact 140 is aligned with the carrier 200 such that the first protrusion 201 aligns with the spring-contact alignment notch 147. The additional spring contact 185 comprises an edge comprising an additional spring-contact alignment notch 181. The additional spring contact 185 is aligned with the carrier 200 such that the second protrusion 202 aligns with the additional spring-contact alignment notch 181. The first protrusion 201 and the second protrusion 202 may be configured, as illustrated in FIG. 1H, such that the spring portion 142 and the additional spring portion 189 extend from the trace-contact interface 103 and the additional trace-contact interface 187 in the same direction. In other examples, the first protrusion 201 and the second protrusion 202 may be configured such that the spring portion 142 and the additional spring portion 189 extend in opposite directions. The alignment of the notches and protrusions provide positive alignment of the spring contact 140 and the additional spring contact 185 such that they maintain electrical isolation from one another. In some examples, the carrier 200 comprises more than two protrusions and each of the spring contact 140 and the additional spring contact 185 comprise more than one alignment notch. Additional protrusions and notches may provide the benefit of positive alignment of the spring contacts with the carrier in additional directions.

FIGS. 1I and 1J are a top schematic view and an exploded schematic side view of a flexible interconnect circuit 100 comprising a shield enclosure, a spring contact 140, and a additional spring contact 185, in accordance with some examples. In some examples, the flexible interconnect circuit 100 further comprises a shield enclosure 179. The shield enclosure 179 comprises a first contact opening 205 and a second contact opening 206. In these examples, carrier 200, the spring contact 140, and the additional spring contact 185 are positioned within the shield enclosure 179 such that at least a portion of the spring contact 140 protrudes the first contact opening 205 and at least a portion of the additional spring contact 185 protrudes through the second contact opening 206. The shield enclosure 179 may be formed from a conductive material including copper, copper alloy, an aluminum alloy, steel, or a plastic resin comprising a conductive filler. When inserted into the shield enclosure 179, the spring contact 140 and the additional spring contact 185 are aligned by the carrier 200 such that both maintain electrical insulation from the shield enclosure 179.

When the flexible interconnect circuit 100 comprises shield layers as described in detail below in relation to FIG. 3B, the shield enclosure 179 may be configured to make electrical contact with shield layers of the flexible interconnect circuit 100 but remain electrically isolated from the conductive trace 130 and the additional conductive trace 183. The shield enclosure 179 may also make electrical contact with external components to which the flexible interconnect circuit 100 is connected, thereby providing electromagnetic shielding to otherwise unshielded portions of the flexible interconnect circuit 100. This may be especially beneficial when high voltages are used, which can cause electromagnetic interference.

### FIG. 2A-2C—Examples of High-Current Spring Contacts

FIGS. 2A-2B are side and top schematic views of flexible interconnect circuit 100 comprising multiple conductive traces 130, all connected to the same spring contact 140. This type of spring contact 140 comprises multiple spring portions, which may be referred to as arch portions 145 and which are monolithic with one base portion 141. Flexible interconnect circuit 100 further comprises additional conductive trace 135 at least partially protruding between first insulator 110 and second insulator 120. Additional conductive trace 135 comprises additional trace contact portion 136 extending past at least one of first insulator 110 and second insulator 120. Base portion 141 of spring contact 140 further directly interfaces and is mechanically attached and electrically connected to additional trace contact portion 136 forming an additional trace-contact interface 104. Base portion 141 comprises first sub-base 143 and second sub-base 144, extending parallel to first sub-base 143 and positioned further away from first insulator 110. Spring portion 142 comprises plurality of arch portions 145, extending parallel to each other and arching over base portion 141 and each comprising first end and second end. First end of each of plurality of arch portions 145 is connected to first sub-base 143. Second end of each of plurality of arch portions 145 is connected to second sub-base 144. In some examples, first sub-base 143, second sub-base 144, and plurality of arch portions 145 are monolithic. In some examples, base portion 141 further comprises a bridging portion 146, extending between and monolithic with first sub-base 143 and second sub-base 144.

FIG. 2B illustrates a top view of flexible interconnect circuit 100 comprising multiple conductive traces 130 matched with single spring contact 140. In this example, spring contact 140 interconnects these conductive traces 130 such that a separate interconnect is not needed. In some examples, at least two, three, four, or more conductive traces 130 are connected to single spring contact 140. As noted above, single spring contact 140 is made up of first sub-base 143 and second sub-base 144 and multiple arch portions 145, which are split apart to form gaps between individual arch portions 145. This gap between arch portions 145 allows for a more flexible single spring contact 140. This allows a device to interconnect with a single component versus multiple components. In some examples, the width (in the Y direction) of each gap relative to the width of the adjacent arch portion 145 is less than 50%, less than 30%, or even less than 10%. In general, the width of these gaps can be minimized to increase the current carrying capability of spring contact 140.

FIG. 2C illustrates a top view of flexible interconnect circuit 100 comprising single conductive trace 130 matched with single spring contact 140. This type of conductive trace 130 and spring contact 140 can be used for high-current applications and/or voltages. In some examples, spring contact 140 has a current rating of 200-600 Amps or, more specifically, 300-500 Amps. In some examples, spring contact 140 has a voltage rating of at least 400 Volts, at least 600 Volts, or even at least 800 Volts. In these examples, the width (the Y-direction) to thickness (the Z-direction) ratio of conductive trace 130 can be at least 10, at least 25, or even at least 50.

### FIGS. 3A-3F—Examples of Two-Side Connections

FIGS. 3A and 3B are side schematic views of two examples of flexible interconnect circuit 100 comprising two spring contacts, i.e., spring contact 140 and additional spring contact 150, attached to opposite sides of circuit 100. Flexible interconnect circuit 100 comprises additional conductive trace 135 and additional spring contact 150. Second insulator 120 is positioned between conductive trace 130 and additional conductive trace 135 forming a stack and electronically insulating conductive trace 130 from additional conduct trace 135. Additional spring contact 150 directly interfaces and is mechanically attached and electrically connected to additional conductive trace 135 such that stack of conductive trace 130, second insulator 120, and additional conductive trace 135 is positioned between spring contact 140 and additional spring contact 150. Second insulator 120 extends past first insulator 110 and also past each of spring contact 140 and additional spring contact 150 thereby preventing arcing between spring contact 140 and additional spring contact 150. Flexible interconnect circuit 100 further comprises third insulator 125. Additional conductive trace 135 at least partially protruding between third insulator 125 and second insulator 120 and comprising an additional trace contact portion 136 extending past at least one of third insulator 125 and second insulator 120. Additional spring contact 150 comprises an additional base portion 151 and an additional spring portion 152 monolithic with additional base portion 151. Additional base portion 151 directly interfaces and is mechanically attached and electrically connected to the additional trace contact portion 136 forming an additional trace-contact interface 109, parallel to trace-contact interface 103. Additional spring portion 152 is configured to flex relative to additional base portion 151 at least in a direction substantially perpendicular to additional trace-contact interface 109.

FIG. 3B illustrates flexible interconnect circuit 100 further comprises shield 161 which is electromagnetic and shield insulator 163. Conductive trace 130 is stacked between shield 161 and additional conductive trace 135. Shield 161 is stacked between shield insulator 163 and first insulator 110. Flexible interconnect circuit 100 further comprises additional shield 162 and an additional shield insulator 164. Additional conductive trace 135 is stacked between additional shield 162 and conductive trace 130. Both conductive trace 130 and additional conductive trace 135 are stacked between shield 161 and additional shield 162. Additional shield 162 is stacked between additional shield insulator 164 and third insulator 125.

Shield 161 and additional shield insulator 164 are added when high voltage is used because an electromagnetic field is created and can create interference, therefore shields 161 and additional shield insulator 164 are used to protect conductive trace 130.

FIGS. 3C and 3D are schematic top and side views of an example of a flexible interconnect circuit 100 comprising a first insulator 110, a second insulator 120, a conductive trace 130, and a spring contact 140, in accordance with some examples. Examples of the first insulator 110, the second insulator 120, the conductive trace 130, and the spring contact 140 are described in detail above. The spring contact 140 comprises at least one spring-contact alignment notch 155. In some examples, the spring contact 140 comprises two or more than two spring-contact alignment notches. The conductive trace 130 comprises at least one conductive-trace alignment notch 157. In some examples, the conductive trace 130 comprises two or more than two conductive-trace alignment notches. The at least one spring-contact alignment notch 155 is aligned with the at least one conductive-trace alignment notch 157. A surface projected by the at least one conductive-trace alignment notch 157 on a plane parallel with the trace-contact interface 103 may be larger than a surface projected by the at least one spring-contact alignment notch 155 on the same plane. Alignment of the at least one spring-contact alignment notch 155 and the at least one conductive-trace alignment notch 157 means that at least a portion of the surface projected by the at least one spring-contact alignment notch 155 is within the surface projected by the at least one conductive-trace alignment notch 157. In some examples where there are two or more spring-contact alignment notches, the size of one of the two or more notches may be larger than the size of one other of the two or more notches.

Different sized notches may provide a benefit of positive orientation control when the flexible interconnect circuit 100 is inserted into a connector. Specifically, the connector may comprise protrusions of different sizes that with the notches when the flexible interconnect circuit 100 is inserted in a correct orientation in the connector, but do not align when the flexible interconnect circuit 100 is inserted in any other orientation.

In some examples, the spring contact 140 of the flexible interconnect circuit 100 comprises an edge extending past the first insulator 110 and the second insulator 120 in at least one direction a distance of DN. In some of these examples, the surface projected by the at least one spring-contact alignment notch 155 on a plane parallel with the trace-contact interface 103 does not interface the conductive trace 130. In some further examples, the spring contact 140 may have two or more edges that extend past the first insulator 110 and the second insulator 120 in other directions.

In some examples, the base portion 141 of the flexible interconnect circuit 100 comprises a surface opposite the conductive trace 130 and at least one overpressure-limiting boss 148 protruding from the surface. In some further examples, the base portion 141 comprises, two, three, four, or even more than four overpressure-limiting bosses. The at least one overpressure-limiting boss 148 has a thickness measured from the surface of the 141 and in a direction perpendicular to the trace-contact interface 103 of TB. The thickness TB is less than a thickness Ts, measured in the same direction from the surface of the 141, that the spring portion 142 protrudes, when not compressed. When the spring contact 140 is inserted in an external connector, the spring contact 140 may compress in a direction substantially perpendicular to the trace-contact interface 103. However, the at least one overpressure-limiting boss 148 does not compress when the spring contact 140 is inserted into an external connector. In this way, the at least one overpressure-limiting boss 148 limits the distance that the spring contact 140 may be urged towards an external connector while allowing the spring contact 140 to compress. The thickness TB may be greater than 0.5 millimeters, greater than 1 millimeter, or even greater than 2 millimeters. The thickness Ts may be less than 3 millimeters, less than 1.5 millimeters, or even less than 0.75 millimeters.

FIG. 3E is a schematic side view of an example of an assembly comprising the flexible interconnect circuit 100 of FIG. 3C, an additional flexible interconnect circuit 320, a stiffener 345, and a connector body 308, in accordance with some examples. The flexible interconnect circuit 100 comprises a first insulator 110, a second insulator 120, a conductive trace 130 at least partially protruding between the first insulator 110 and the second insulator 120. The flexible interconnect circuit 100 comprises a trace contact portion 131 extending past at least one of the first insulator 110 and the second insulator 120. The flexible interconnect circuit 100 further comprises a spring contact 140 comprising a base portion 141 and a spring portion 142 monolithic with the base portion 141, electrically and mechanically coupled with the conductive trace 130, forming a trace-contact interface 103. The spring portion 142 is configured to flex relative to the base portion 141 at least in a direction substantially perpendicular to the trace-contact interface 103. The additional flexible interconnect circuit 320 comprises an additional first insulator 325, an additional second insulator 335, an additional conductive trace 330 at least partially protruding between the additional first insulator 325 and the additional second insulator 335. The additional flexible interconnect circuit 320 also comprises an additional trace contact portion 331 extending past at least one of the additional first insulator 325 and the additional second insulator 335. The additional flexible interconnect circuit 320 further comprises an additional spring contact 340 comprising an additional base portion 341 and an additional spring portion 342 monolithic with the additional base portion 341, electrically and mechanically coupled with the additional conductive trace 330 forming an additional trace-contact interface 333. The additional spring portion 342 is configured to flex relative to the additional base portion 341 at least in a direction substantially perpendicular to the additional trace-contact interface 333.

The stiffener 345 is positioned between the flexible interconnect circuit 100 and the additional flexible interconnect circuit 320. The stiffener 345 may be formed from a material such as a polymer resin or a glass fiber reinforced epoxy. The stiffener 345 may have a thickness greater than 0.2 millimeters, greater than 0.4 millimeters, greater than 0.5 millimeters, greater than 0.75 millimeters, greater than 1 millimeter, greater than 2 millimeters, greater than 4 millimeters, or even greater than 8 millimeters. The stiffener 345 may have a thickness less than 6 millimeters, less than 3.5 millimeters, less than 2.5 millimeters, or even less than 1.5 millimeters.

The connector body 308 directly interfaces the flexible interconnect circuit 100 and the additional flexible interconnect circuit 320. The connector body 308 is configured to urge the flexible interconnect circuit 100 and the additional flexible interconnect circuit 320 towards the stiffener 345. In some examples, the connector body 308 interfaces the flexible interconnect circuit 100 on a side that is opposite the side of the additional flexible interconnect circuit 320 that the connector body 308 interfaces. In other examples, the connector body 308 interfaces multiple sides of both the flexible interconnect circuit 100 and the additional flexible interconnect circuit 320. The connector body 308 may be formed from a polymer resin.

In some examples, the assembly 300 further comprises a blade header 302. The 302 comprises a blade-header axis 301, a blade conductor 303, a additional blade conductor 306, and a pressure ramp 305. The blade conductor 303 extends parallel with the blade-header axis 301 and is formed from a conductive material. The blade conductor 303 may be formed from, for example, steel, copper, a copper alloy, an aluminum alloy, tin-coated nickel, or tin-coated steel. The additional blade conductor 306 extends parallel with the blade conductor 303 but is electrically isolated from the blade conductor 303. The additional blade conductor 306 may be formed from any of the same materials as the blade conductor 303. The pressure ramp 305 is positioned at an end of the blade header 302 and between the blade conductor 303 and the additional blade conductor 306. Apart from the blade conductor 303 and the additional blade conductor 306, the blade header 302 (including the pressure ramp 305) may be formed from a polymer resin.

In some examples, the pressure ramp 305 extends parallel with the blade-header axis 301. The pressure ramp 305 is configured to apply forces to the flexible interconnect circuit 100 and the additional flexible interconnect circuit 320 when the flexible interconnect circuit 100 and the additional flexible interconnect circuit 320 are inserted into the blade header 302. In this way, the forces applied by the pressure ramp 305 urge the spring portion 142 towards the blade conductor 303 and the additional spring portion 342 towards the additional blade conductor 306, thereby electrically connecting the conductive trace 130 with the blade conductor 303 and the additional conductive trace 330 with the additional blade conductor 306. The additional flexible interconnect circuit 320 may comprise at least one overpressure-limiting boss 148 as described above for the flexible interconnect circuit 100. In some examples, the pressure ramp 305 prevents undesired contact of external objects with either of the blade conductor 303 or the additional blade conductor 306 when the flexible interconnect circuit 100 and the additional flexible interconnect circuit 320 are not inserted into the blade header 302. Specifically, the position and length of the pressure ramp 305 in a direction parallel with the blade-header axis 301 may provide touch projection to the blade conductor 303 and the additional blade conductor 306.

In some examples, the blade header 302 further comprises a conductor support 304 interfacing the blade conductor 303. The configured to mechanically support the blade conductor 303 against a force applied by the spring portion 142 when the pressure ramp 305 applies a force to urge the spring portion 142 towards the blade conductor 303.

In some examples, the assembly 300 further comprises a third flexible interconnect circuit 360, a fourth flexible interconnect circuit 370, an additional stiffener 346, and an additional connector body 309. FIG. 3F illustrates an assembly 300 interconnecting two pairs of flexible interconnect circuits, in accordance with some examples. The third flexible interconnect circuit 360 comprises a third conductive trace 362 and a third spring contact 364 electrically and mechanically coupled with the third conductive trace 362. The third spring contact 364 comprises a third base portion 366 and a third spring portion 368 monolithic with the third base portion 366. The fourth flexible interconnect circuit 370 comprises a fourth conductive trace 372 and a fourth spring contact 374 electrically and mechanically coupled with the fourth conductive trace 372. The fourth spring contact 374 comprises a fourth base portion 376 and a fourth spring portion 378 monolithic with the fourth base portion 376. The additional stiffener 346 is positioned between the third flexible interconnect circuit 360 and the fourth flexible interconnect circuit 370. The properties of the additional stiffener 346 are as described above for the stiffener 345. The additional connector body 309 directly interfaces the third flexible interconnect circuit 360 and the fourth flexible interconnect circuit 370. The additional connector body 309 is configured to urge the third flexible interconnect circuit 360 and the fourth flexible interconnect circuit 370 towards the additional stiffener 346.

In these examples, the blade header 302 further comprises an additional pressure ramp 311 positioned at an opposite end of the blade header 302 from the pressure ramp 305. The additional pressure ramp 311 is configured to apply forces to the third flexible interconnect circuit 360 and the fourth flexible interconnect circuit 370 when the third flexible interconnect circuit 360 and the fourth flexible interconnect circuit 370 are inserted into the blade header 302. These forces urge the third spring portion 368 towards the blade conductor 303 and the fourth spring portion 378 towards the additional blade conductor 306, thereby electrically connecting the third conductive trace 362 with the blade conductor 303 and the fourth conductive trace 372 with the additional blade conductor 306.

In some further examples, the blade header 302 protrudes through an opening 352 in a mounting surface 350. In these examples, the blade conductor 303 and the additional blade conductor 306 are electrically isolated from the mounting surface 350. In some examples, when the blade header 302 protrudes through a mounting surface 350, the direction in which it protrudes is substantially parallel with the blade-header axis 301. In this way, the assembly 300 may be used as a pass-through fitting for connecting high voltage wires while maintaining their electrical isolation from the mounting surface 350.

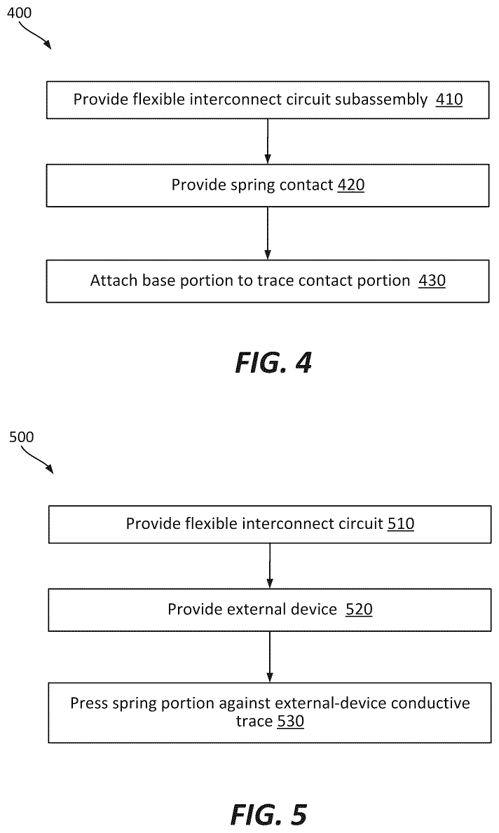

### FIG. 4—Methods of Fabricating Flexible Interconnect Circuits

FIG. 4 illustrates a process flowchart corresponding to method 400 of fabricating flexible interconnect circuit 100 comprising one or more spring contacts 140 connected to one or more conductive traces 130. Various examples of flexible interconnect circuit 100 are described above.

Method 400 comprises providing (block 410) a flexible interconnect circuit subassembly comprising first insulator 110 and conductive trace 130 laminated to first insulator 110. In some examples, the flexible interconnect circuit subassembly also comprises second insulator 120 such that conductive trace 130 is positioned between first insulator 110 and second insulator 120. Conductive trace 130 comprises trace contact portion 131 extending past at least one of first insulator 110. In some examples, trace contact portion 131 is laminated to and supported by second insulator 120. Furthermore, in some examples, flexible interconnect circuit 100 comprises additional conductive trace 135, which may or may not be connected to spring contact 140 in the latest operation.

Method 400 comprises providing (block 420) spring contact 140 comprising base portion 141 and spring portion 142 monolithic with base portion 141. Various examples of spring contact 140 are described above.

Method 400 comprises attaching (block 430) base portion 141 of spring contact 140 to trace contact portion 131 of the flexible interconnect circuit subassembly such that after attaching base portion 141 directly interfaces and is mechanically attached and electrically connected to trace contact portion 131 forming trace-contact interface 103 and spring portion 142 is configured to flex relative to the base portion 141 at least in a direction substantially perpendicular to trace-contact interface 103.

In some examples, attaching (block 430) base portion 141 of spring contact 140 to trace contact portion 131 of flexible interconnect circuit subassembly comprises one or more laser welding and ultrasonic welding.

In some examples, while attaching (block 430) base portion 141 of spring contact 140 to trace contact portion 131 of flexible interconnect circuit subassembly, a portion of a surface of trace contact portion 131, facing away from base portion 141, is exposed.

In some examples, method 400 further comprises, after attaching (block 430) base portion 141 of spring contact 140 to trace contact portion 131 of flexible interconnect circuit subassembly, laminating a second insulator 120 to conductive trace 130 such that portion of the surface of trace contact portion 131, facing away from base portion 141, is covered with second insulator 120.

In some examples, providing flexible interconnect circuit subassembly comprises patterning a metal foil to form a conductive trace 130 such that conductive trace 130 is laminated to and supported by first insulator 110 relative to other conductive traces 130 formed from same metal foil.

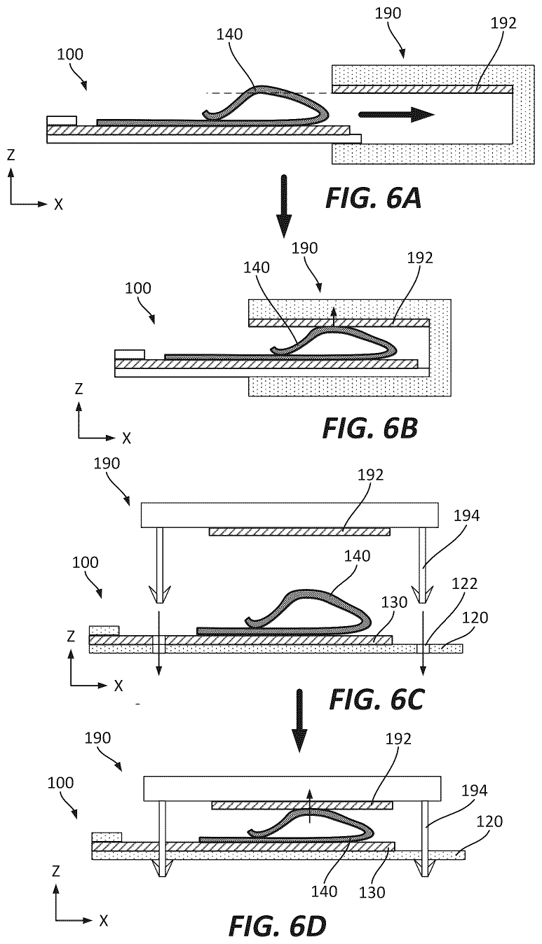

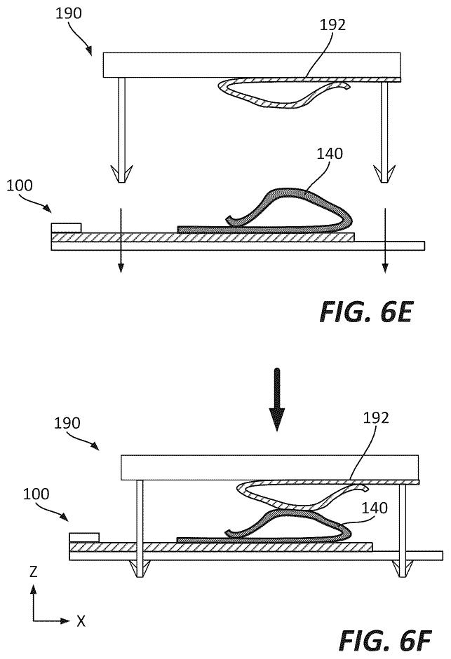

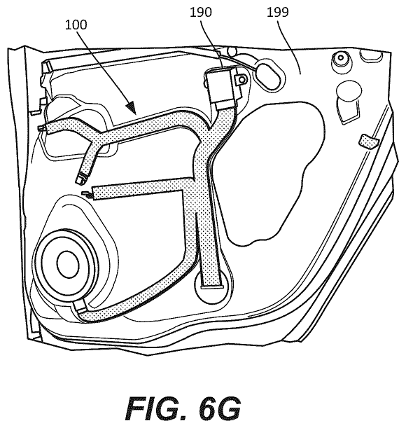

FIGS. 5 and 6A-6F—Examples of Methods for Forming Electrical Connections Using Flexible Interconnect Circuits with Spring Contacts

FIG. 5 illustrates a process flowchart corresponding to method 500 of forming electrical connections to flexible interconnect circuit 100 using one or more spring contacts 140 of circuit 100. Various examples of flexible interconnect circuit 100 are described above.

Method 500 comprises providing (block 510) flexible 100 comprising first insulator 110, second insulator 120, conductive trace 130, and spring contact 140. Conductive trace 130 at least partially protrudes between first insulator 110 and second insulator 120 and comprises trace contact portion 131 extending past at least one of first insulator 110 and second insulator 120. Spring contact 140 comprises a base portion 141 and a spring portion 142 monolithic with base portion 141. Base portion 141 directly interfaces and is mechanically attached and electrically connected to trace contact portion 131 forming a trace-contact interface 103. Spring portion 142 is configured to flex relative to base portion 141 at least in a direction substantially perpendicular to trace-contact interface 103.

In some examples, method 500 further comprises providing (block 520) external device 190 comprising an external-device conductive trace 192. Various types of external device 190 are within the scope, e.g., automotive components such as seats, lights, and the like.

In some examples, method 500 further comprises pressing (block 530) spring portion 142 of spring contact 140 against external-device conductive trace 192 of external device 190 such that, during pressing, spring portion 142 deforms and is positioned closer to base portion 141. In some examples, pressing spring portion 142 of spring contact 140 against external-device conductive trace 192 of external device 190 coincides with pressing an additional spring portion 152 of an additional spring contact 150 against an external-device conductive trace of external device 190. Furthermore, in some examples, this operation comprises interlocking one or more components of flexible interconnect circuit 100 with the external device 190 as will now be described with reference to FIGS. 6A-6F.

FIGS. 6A-6F illustrate schematic views of different states of the method described in FIG. 5. Specifically, FIG. 6A illustrates a schematic view of flexible interconnect circuit 100 entering external device 190 comprising external-device conductive trace 192. For example, this external device 190 can be a connector socket. FIG. 6B illustrates a schematic view of flexible interconnect circuit 100 inside of external device 190. Upon entering the external device 190, spring contact 140 is compressed such that when inside the external device 190, the spring contact 140 presses on external-device conductive trace 192 thereby forming a contact.

FIG. 6C illustrates a schematic view of external device 190 comprising a set of retaining protrusions 194, second insulator 120 comprising a set of openings 122. Wherein spring contact 140 pressed against external-device conductive trace 192 of external device 190 and further comprises extending set of retaining protrusions 194 through set of openings 122. Similar to the example in FIGS. 6A-6B, in this example, spring contact 140 is flexed thereby causing the spring contact 140 to apply a force against external-device conductive trace 192. FIG. 6D illustrates a schematic view of wherein after spring contact 140 is pressed against external-device conductive trace 192 of external device 190 flexible interconnect circuit 100 is mechanically coupled to external device 190.

In some examples, the automotive industry may use a roll of flexible interconnect circuit 100 to be used for alerting a driver that a seat belt is not in use. External device 190 may be a car seat sensor. Instead of multiple steps being needed to attach the external device 190 to circuit 100, retaining protrusions 194 and set of openings 122 allow for a roll of flexible interconnect circuit 100 to be rolled out and the external device 190 pressed against circuit 100 in one step. See FIG. 5 for full details of this method.

In some examples, both contacting surfaces are designed to flex when forming a connection, e.g., as shown in FIGS. 6E-6F. FIG. 6E illustrates a schematic view of external device 190 with conductive trace 192 that has a similar shape as spring contact 140 of flexible interconnect circuit 100 before forming a connection between external-device conductive trace 192 and spring contact 140. FIG. 6F illustrates a schematic view of external device 190 and flexible interconnect circuit 100 after the connection between external-device conductive trace 192 and spring contact 140 is formed. At this point, both external-device conductive trace 192 and spring contact 140 can be flexed thereby causing a combined force at the interface.

FIG. 6G illustrates an example of external device 190, which is a car door 199. Other examples are within the scope. Specifically, flexible interconnect circuit 100 can be used as a car-door wire harness for interconnecting various components of the door (e.g., power windows, power door locks, speakers, and the like). These connections may be formed using spring contacts 140 of flexible interconnect circuit 100 as described above. The use of spring contacts 140 expedites the process of the door assembly by eliminating the need to slide in connectors (e.g., in a conventional assembly process), which can be strenuous to the operators.

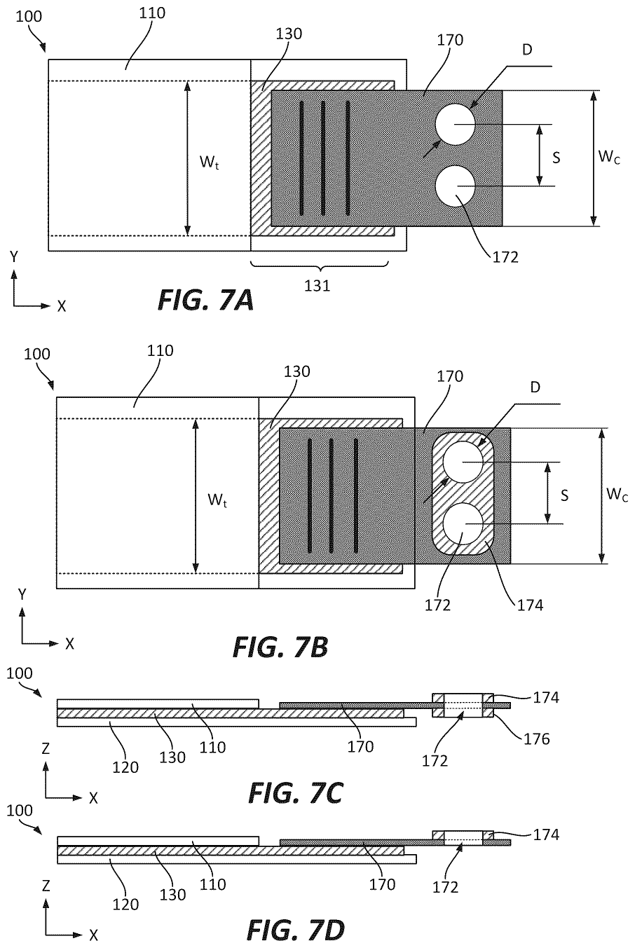

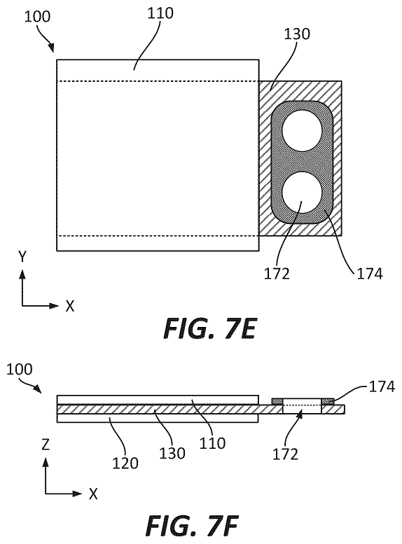

### FIG. 7A-7F—Examples of Rotation Prevention Features

FIGS. 7A and 7B illustrate top schematic views of two examples of flexible interconnect circuit 100 comprising first insulator 110, second insulator 120, conductive trace 130, and connection tab 170. Connection tab 170 can be made of a thin sheet metal which helps reduce heat and create more surface area. For example, connection tab 170 can be formed from aluminum, copper, nickel, stainless steel, and other like materials. The material of connection tab 170 can be the same as the material of conductive trace 130 or different. For example, conductive trace 130 can be formed from aluminum, while connection tab 170 can be formed from nickel. The thickness of connection tab 170 can be greater than that of conductive trace 130 to ensure the mechanical strength of the connection tab 170 and enable the rotation-prevention features of connection tab 170. Wherein, conductive trace 130 at least partially protruding between first insulator 110 and second insulator 120 comprises trace contact portion 131 extending past at least one of first insulator 110 and second insulator 120.

Connection tab 170 comprises at least two connection openings 172 and directly interfacing and is mechanically attached and electrically connected to trace contact portion 131 forming trace-contact interface 103. In some examples, connection openings 172 are aligned along an axis perpendicular to the length of conductive trace 130. Connection openings 172 of connection tab 170 are used to prevent rotation when an attachment device is used to attach flexible interconnect circuit 100 to an external device 190 through connection opening 172. In some examples, the diameter of each of connection openings 172 is at least 2 millimeters or even at least 5 millimeters. Furthermore, the distance between the centers of connection openings 172 can be at least 6 millimeters, at least 10 millimeters, or even at least 20 millimeters. A combination of these dimensions enables the rotation-prevention features of connection tab 170.

Specifically in FIG. 7B, flexible interconnect circuit 100 further comprises reinforcement component 174 to build the thickness of connection tab 170, attached to connection tab 170 and overlapping with all connection openings 172 such that connection openings 172 further protrude through reinforcement component 174. In some examples, reinforcement component 174 is made from an insulating material. Alternatively, reinforcement component 174 is made from a conductive material (the same or different from the material of connection tab 170) and may be used to form electrical connections.

FIGS. 7C and 7D illustrate side schematic views of two examples of flexible interconnect circuit 100 from FIGS. 7A and 7B but further comprises additional reinforcement component 176, attached to connection tab 170 such that connection tab 170 is positioned between reinforcement component 174 and additional reinforcement component 176, wherein additional reinforcement component 176 overlaps with all of connection openings 172 such that connection openings 172 further protrude through additional reinforcement component 176. In some examples, reinforcement component 174 is offset relative to conductive trace 130 such that neither one of the connection openings 172 protrudes through conductive trace 130.

FIGS. 7E and 7D illustrate top and side schematic views of reinforcement component 174 attached to conductive trace 130 without trace contact portion 131 as shown in FIGS. 7A and 7B.

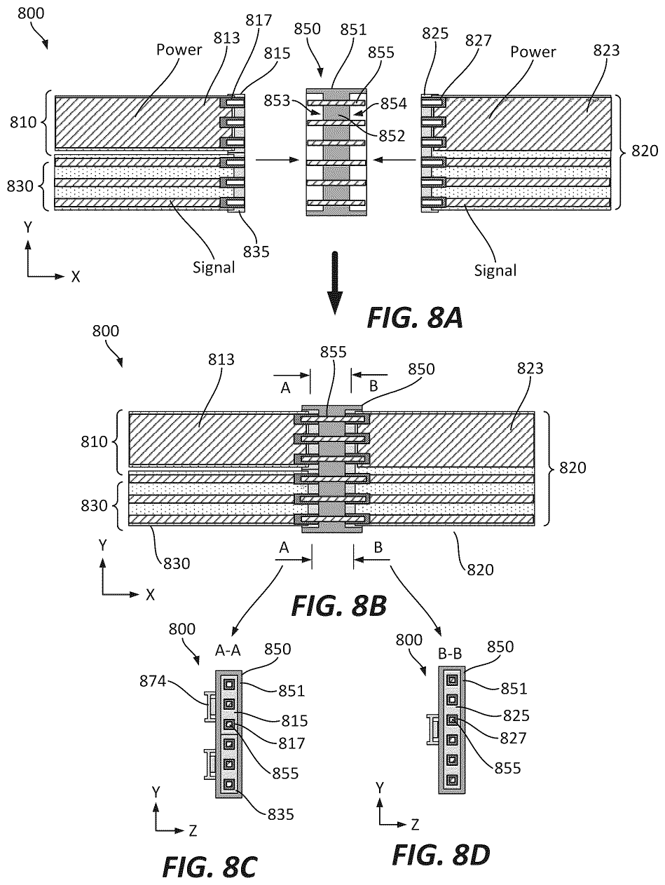

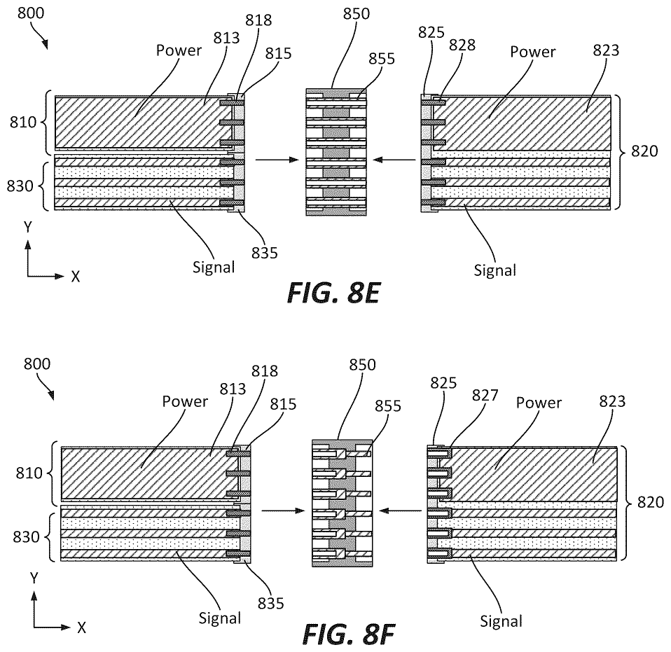

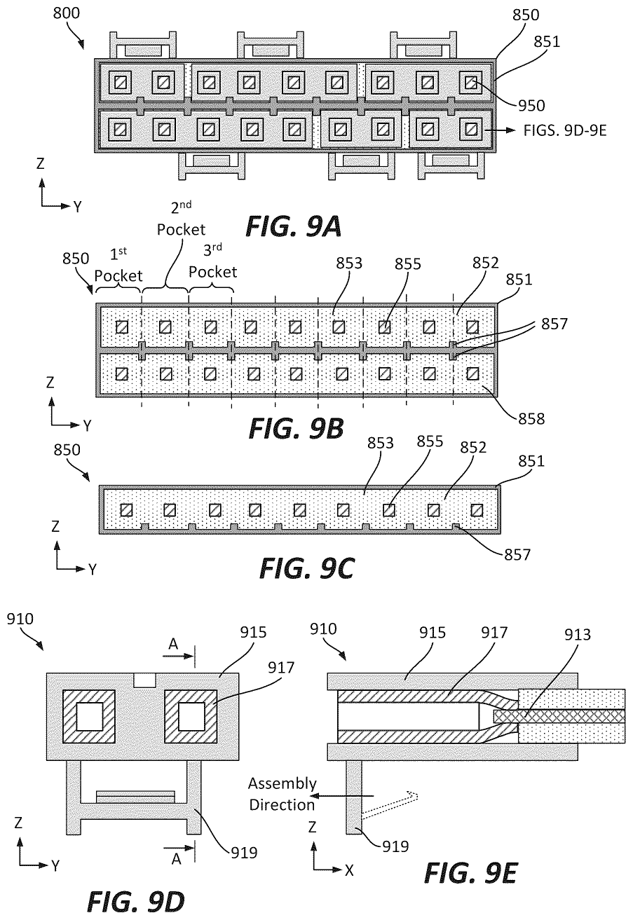

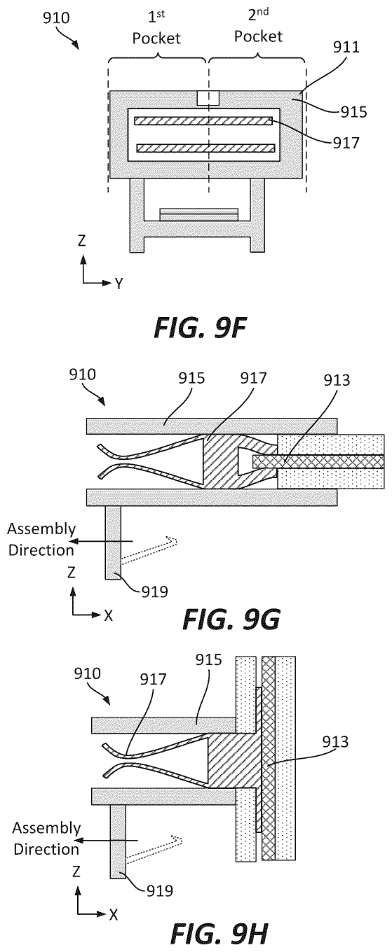

### FIGS. 8A-8F and 9A-9H—Modular Junction Connector Examples

FIGS. 8A and 8B illustrate an example of assembly 800 made up of first flexible interconnect circuit 810, second flexible interconnect circuit 820, third flexible interconnect circuit 830, and modular junction connection 850. First flexible interconnect circuit 810 comprises first conductive trace 813, first connector body 815, and first set of connector units 817 wherein each unit 817 is connected to first conductive trace 813 and supported by first connector body 815. Second flexible interconnect circuit 820 comprises second conductive trace 823, second connector body 825, and second set of connector units 827 wherein at least one unit 827 is connected to second conductive trace 823 and supported by second connector body 825. Multiple flexible interconnect circuits connected to modular junction connector 850 indicate the flexibility in how many devices/circuits can be connected at one time instead of the traditional circuit modular connection where only a circuit with the correct number of interconnecting units can attach to a specific modular junction connector.

Modular junction connector 850 comprises connector body 851 and set of interconnecting units 855 supported by connector body 851. The connector body 851 of modular junction connector 850 comprises first open cavity 853 and second open cavity 854 that are both separated by wall 852 such that an opening of first open cavity 853 face in an opposite direction from an opening of second open cavity 854. Further, third flexible interconnect circuit 830 can also be part of assembly 800 and comprises third body connector body 835. Third flexible interconnect circuit 830 and third body connector body 835 are separate from first flexible interconnect circuit 810. Set of interconnecting units 855 can also be called set of pins. This configuration creates an improvement on previous configurations where only signal was generated and very little power. Now both signal and a higher power are created through each conductive trace 130 found on each flexible interconnect circuit 100 that are connected via modular junction connector 850.

FIG. 8B illustrates another example of assembly 800, more specifically, first flexible interconnect circuit 810 and second flexible interconnect circuit 820 connected to opposing sides of modular junction connection 850. Set of interconnecting units 855 protrude through wall 852 and partially extend into each of first open cavity 853 and second open cavity 854. One interconnecting unit 855 protrudes into one of first set of connector units 817 and also into one of second set of connector units 827 thereby interconnecting first conductive trace 813 and second conductive trace 823. First connector body 815 at least partially extends into first open cavity 853 and is interlocked with connector body 851. Second connector body 825 at least partially extends into second open cavity 854 and is interlocked with connector body 851.

FIGS. 8C and 8D illustrate a cross-sectional view of modular junction connector 850 in FIG. 8B with connector bodies 851 extending into connector cavities 853, 854 and set of interconnecting units 855 extending in and connecting to connector units 817, 827. Assembly 800 can also contain interlocking units 874 on the exterior of modular junction connector 850, interlocking with connector bodies 851. This also shows the improvement from previous circuit connections where only a circuit with the correct number of interconnecting units can attach to a specific modular junction connector In some examples, first set of connector units 817 and second set of connector units 827 have a different number of units. In some additional examples, third connector body 835 at least partially extends into first open cavity 853 and is interlocked with connector body 851.

FIGS. 8E and 8F illustrate schematic cross-sectional views of two additional examples of an assembly 800 comprising three flexible interconnect circuits 810, 820, 830 and modular junction connector 850 before interconnecting these flexible interconnect circuits 810, 820, 830 using modular junction connector 850, in accordance with some examples. FIG. 8E illustrates assembly 800 wherein modular junction connector 850 comprises hollow set of interconnecting units 855 instead of solid set of interconnecting units or pins 855 and first set of connector units 818 made up of solid pins and second set of connector units 828 made up of solid pins. Thereby the three flexible interconnect circuits 810, 820, 830 are connected to modular junction connector 850 via hollow sets of interconnecting units 855 and sets of solid pin connector units 818, 828. FIG. 8F illustrates assembly 800 wherein modular junction connector 850 comprises hollow set of interconnecting units 855 on the side adjacent to first and third flexible interconnect circuits 810, 830 and solid pin set of interconnecting units 855 on the side adjacent to second flexible interconnect circuit 820. Wherein, first and third flexible interconnect circuits 810, 830 comprise solid pin set of connector units 818 and thereby interconnect with hollow set of interconnecting units 855 side of modular junction connector 850. Further, second flexible interconnect circuit 820 comprises a hollow set of connector units 827, which are configured to interconnect with a solid pin set of interconnecting units 855 side of modular junction connector 850.

FIG. 9A illustrates a cross-sectional view of assembly 800 comprising first flexible interconnect circuit 810 and modular junction connector 850 before interconnecting first flexible interconnect circuit 810 using modular junction connector 850 and multiple connector bodies 851 that extend into connector cavities 853, 854.

FIG. 9B illustrates a front view of modular junction connector 850 of FIG. 9A without any flexible interconnecting circuits 810, 820, 830 connected into cavities. Modular junction connector 850 comprises first open cavity 853 and additional first open cavity 858 which are made up of multiple pockets separated by guiding pins 857, wherein each pocket comprises wall 852 and interconnecting units 855.

FIG. 9C illustrates a front view of another example of modular junction connector 850 but only illustrates single cavity 853. In some examples, an unlimited number of cavities can be added on either side of modular junction connector 850.

FIGS. 9D and 9E illustrate front and side cross-sectional views of connector body 915 of flexible interconnect circuit 910. FIG. 9D illustrates first flexible interconnect circuit 910 made up of first set of connector sockets 917 surrounded by first connector body 915 and connected to an interlocking unit 919. FIG. 9E illustrates first flexible interconnect circuit 910 made up of first set of connector sockets 917 connected to first conductive trace 913 and surrounded by first connector body 915 and connected to interlocking unit 919.

FIG. 9F illustrates another example of flexible interconnect circuit 910 or, more specifically, circuit connector portion 911 or flexible interconnect circuit 910, in accordance with some examples. Circuit connector portion 911 comprises connector body 915 and connector unit 917, which in this example is formed by two leaf springs. Unlike connector units described above in the context of FIGS. 8A-8F (in which each connector unit extends to a single pocket of modular junction connector 850 and engages a separate interconnecting unit in a set of interconnecting units 855), the two leaf springs of connector unit 917 can extend into multiple pockets of modular junction connector 850 (e.g., two pockets in the example shown in FIG. 9F). In some examples, the two leaf springs of connector unit 917 can extend into a single pocket of modular junction connector 850. Alternatively, the two leaf springs of connector unit 917 can extend into three or more pockets of modular junction connector 850. The number of pockets can depend on the current ratings of this particular connection. When engaging an interconnecting unit (in a set of interconnecting units 855), the interconnecting unit can slide between the two leaf springs of connector unit 917 such that these spring leafs press on different sides of the interconnecting unit thereby forming an electric connection.

FIGS. 9G and 9H illustrate different attachment options between connector unit 917 and conductive trace 913 of flexible interconnect circuit 910.

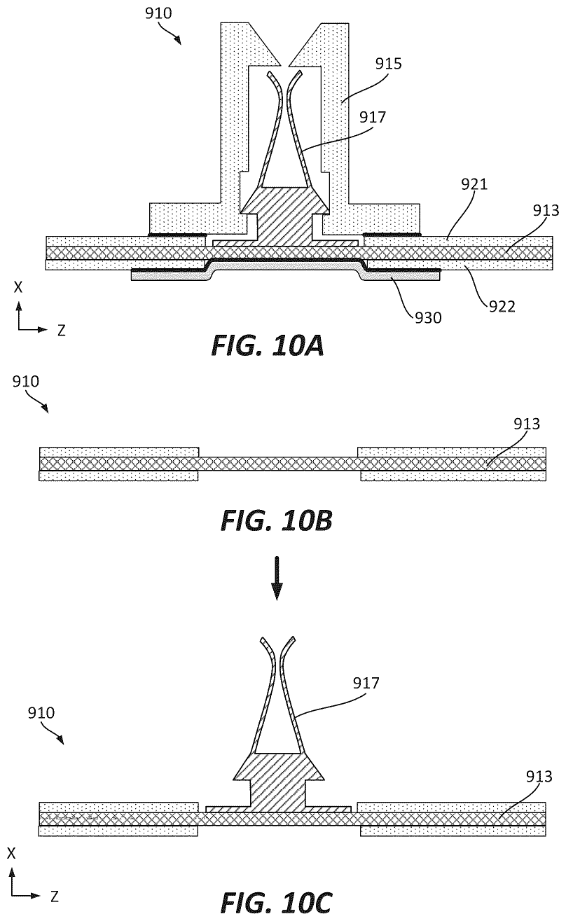

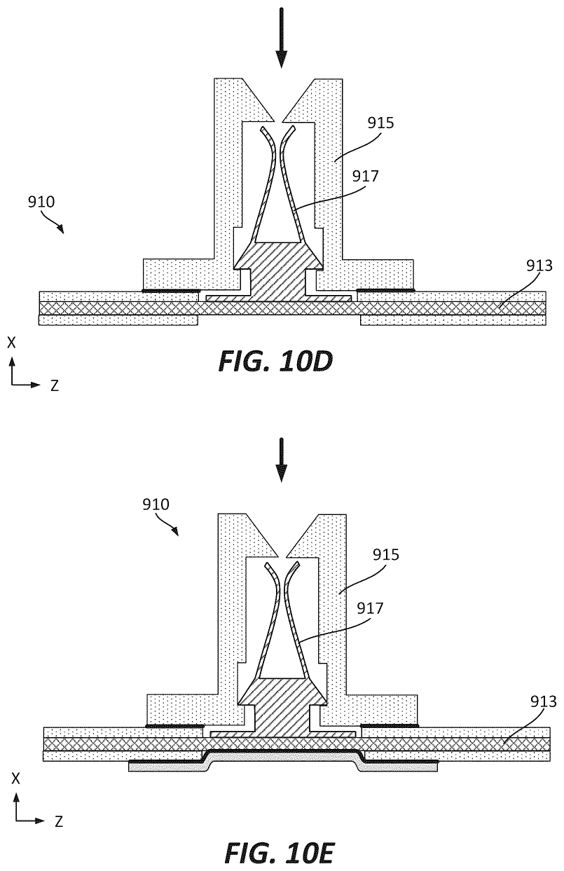

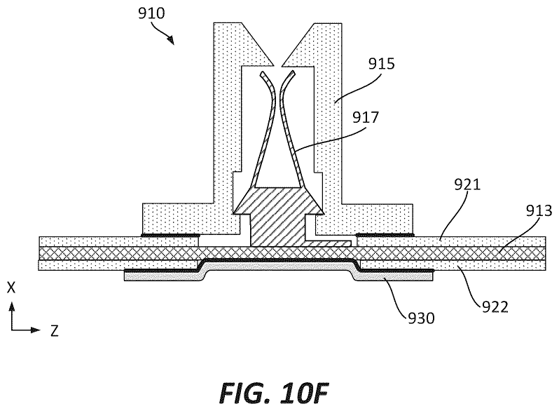

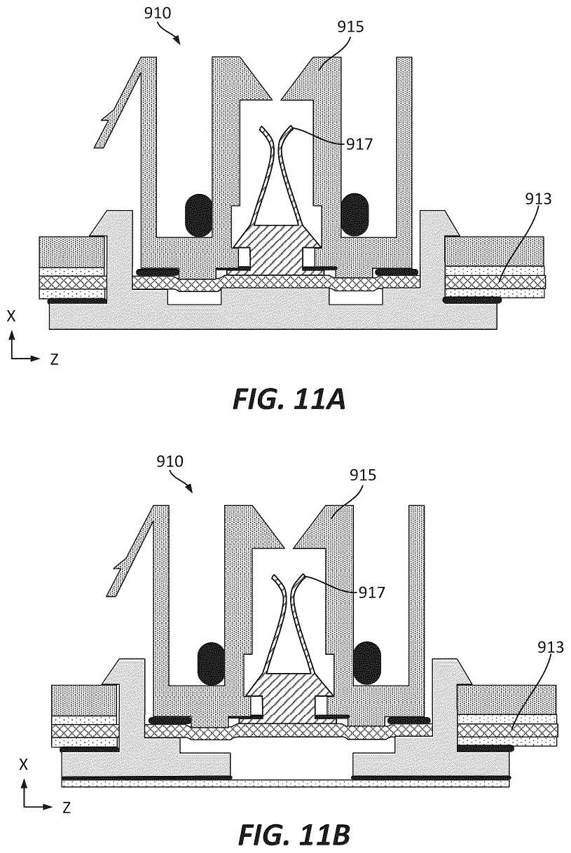

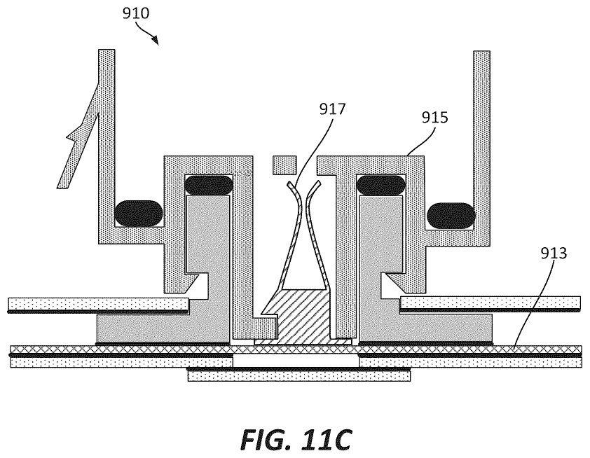

FIGS. 10A-11C—Examples of Flexible Interconnect Circuit with Attached Connector Units

FIGS. 10A and 10F illustrate yet another example of attachment between connector unit 917 and conductive trace 913 of flexible interconnect circuit 910. In these examples, conductive trace 913 is positioned between first insulating layer 921 and second insulating layer 922. Each insulating layer has an opening. Specifically, the opening in first insulating layer 921 is used to protrude connector unit 917 and form direct contact with conductive trace 913. The opening in second insulating layer 922 can be used for forming a contact (e.g., weld) between conductive trace 913 and connector unit 917. Connector body 915 can be slid over and interlocked with connector unit 917 (e.g., as shown in FIG. 10A). Furthermore, connector body 915 can be adhered to first insulating layer 921. The opening in second insulating layer 922 can be sealed with patch 930. FIGS. 10B-10E are schematic cross-sectional views illustrating different stages during the fabrication of the connector portion of flexible interconnect circuit 910 in FIG. 10A, in accordance with some examples. FIGS. 11A-11C are additional examples of the connector portion of flexible interconnect circuit 910, in accordance with some examples.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present examples are to be considered illustrative and not restrictive.

1. A flexible interconnect circuit comprising:
a first insulator;
a second insulator;
a conductive trace at least partially protruding between the first insulator and the second insulator and comprising a trace contact portion extending past at least one of the first insulator and the second insulator; and
a spring contact comprising a base portion and a spring portion monolithic with the base portion, wherein:
the base portion directly interfaces and is mechanically attached and electrically connected to the trace contact portion forming a trace-contact interface,
the spring portion is configured to flex relative to the base portion at least in a direction substantially perpendicular to the trace-contact interface,
each of the first insulator and the second insulator comprises an adhesive sublayer facing the conductive trace, and
at least a portion of the first insulator is directly laminated to at least a portion of the second insulator.

2. The flexible interconnect circuit of claim 1, wherein the spring portion comprises a first sub-arch spring portion 142a and a second sub-arch spring portion 142b, comprising first ends and second ends such that the first ends are monolithic with the base portion and the second ends extend toward each other and are separated by a gap thereby enhancing flexibility of the first sub-arch spring portion 142a and the second sub-arch spring portion 142b.

3. The flexible interconnect circuit of claim 1, wherein the trace contact portion is flexible.

4. The flexible interconnect circuit of claim 1, wherein the trace contact portion further interfaces the second insulator such that the trace contact portion is positioned between the second insulator and the base portion.

5. The flexible interconnect circuit of claim 1, further comprising a stiffening unit such that the trace contact portion is positioned between the stiffening unit and the base portion, wherein:
the stiffening unit comprises a material selected from the group consisting of (1) a composite comprising a fiberglass cloth and an epoxy resin, and (2) polycarbonate, and
the stiffening unit has a thickness of between 2 millimeters and 6 millimeters.

6. The flexible interconnect circuit of claim 5, wherein:
the trace contact portion further interfaces the second insulator,
the second insulator is at least partially positioned between the trace contact portion and the stiffening unit, and
the stiffening unit is mechanically attached to the second insulator.

7. The flexible interconnect circuit of claim 1, wherein the spring contact is narrower than the trace contact portion and is not attached to any other conductive traces of the flexible interconnect circuit.

8. The flexible interconnect circuit of claim 7, wherein each of the conductive trace and the spring contact has a current rating of 2-20 Amps.

9. The flexible interconnect circuit of claim 1, further comprising an additional conductive trace at least partially protruding between the first insulator and the second insulator, wherein:
the additional conductive trace comprises an additional trace contact portion extending past at least one of the first insulator and the second insulator, and
the base portion of the spring contact further directly interfaces and is mechanically attached and electrically connected to the additional trace contact portion forming an additional trace-contact interface.

10. The flexible interconnect circuit of claim 9, wherein the spring contact has a current rating of 200-600 Amps.

11. The flexible interconnect circuit of claim 9, wherein the spring contact has a voltage rating of at least 400 Volts.

12. The flexible interconnect circuit of claim 1, wherein:
the base portion comprises a first sub-base and a second sub-base, extending parallel to the first sub-base and positioned further away from the first insulator,
the spring portion comprises a plurality of arch portions, extending parallel to each other and arching over the base portion and each comprising a first end and a second end,
the first end of each of the plurality of arch portions is connected to the first sub-base, and
the second end of each of the plurality of arch portions is connected to the second sub-base.

13. The flexible interconnect circuit of claim 12, wherein the first sub-base, the second sub-base, and the plurality of arch portions are monolithic.

14. The flexible interconnect circuit of claim 13, wherein the base portion further comprises a bridging portion, extending between and monolithic with the first sub-base and the second sub-base.

15. The flexible interconnect circuit of claim 1, further comprising an additional conductive trace and an additional spring contact, wherein:
the second insulator is positioned between the conductive trace and the additional conductive trace forming a stack and electronically isolating the conductive trace from the additional conductive trace, and
the additional spring contact directly interfaces and is mechanically attached and electrically connected to the additional conductive trace such that a stack of the conductive trace, the second insulator, and the additional conductive trace is positioned between the spring contact and the additional spring contact.

16. The flexible interconnect circuit of claim 15, wherein the second insulator extends past the first insulator and also past each of the spring contact and the additional spring contact thereby preventing arcing between the spring contact and the additional spring contact.

17. The flexible interconnect circuit of claim 15, further comprising a third insulator, wherein:
the additional conductive trace at least partially protrudes between the third insulator and the second insulator and comprises an additional trace contact portion extending past at least one of the third insulator and the second insulator,
the additional spring contact comprises an additional base portion and an additional spring portion monolithic with the additional base portion,
the additional base portion directly interfaces and is mechanically attached and electrically connected to the additional trace contact portion forming an additional trace-contact interface, parallel to the trace-contact interface, and
the additional spring portion is configured to flex relative to the additional base portion at least in a direction substantially perpendicular to the additional trace-contact interface.

18. The flexible interconnect circuit of claim 1, wherein the base portion is mechanically attached and electrically connected to the trace contact portion using laser welding, ultrasonic welding, and soldering.

19. The flexible interconnect circuit of claim 1, wherein the conductive trace has a thickness of at least 100 micrometers.

20. The flexible interconnect circuit of claim 1, wherein the conductive trace comprises aluminum.
